(19) United States
(12) Patent Application Publication
(10) Pub. No.: US 2014/0071761 A1
(43) Pub. Date: Mar. 13, 2014

(54) NON-VOLATILE STORAGE WITH JOINT HARD BIT AND SOFT BIT READING

(71) Applicant: SANDISK TECHNOLOGIES INC., Plano, TX (US)

(72) Inventors: Eran Sharon, Rishon Lezion (IL); Idan Alrod, Herzliya (IL); Yan Li, Milpitas, CA (US); Yee Lih Koh, Fremont, CA (US); Tien-Chien Kuo, Sunnyvale, CA (US)

(73) Assignee: SANDISK TECHNOLOGIES INC., Plano, TX (US)

(21) Appl. No.: 13/743,502

(22) Filed: Jan. 17, 2013

Related U.S. Application Data
(60) Provisional application No. 61/699,021, filed on Sep. 10, 2012.

(51) Int. Cl. G11C 16/26

(52) U.S. Cl. CPC G11C 16/26
USPC 365/185.18

(57) ABSTRACT

A system is disclosed for reading hard bit information and soft bit information from non-volatile storage. Some of the hard bit information and/or soft bit information is read concurrently by using different bit line voltages, different integration times, different sense levels within the sense amplifiers, or other techniques. A method is disclosed for determining the hard bits and soft bits in real time based on sensed hard bit information and soft bit information.

This application claims the benefit of U.S. Provisional Application 61/699,021, NON-VOLATILE STORAGE WITH JOINT HARD BIT AND SOFT BIT READING. filed on Sep. 10, 2012, incorporated herein by reference in its entirety.

### BACKGROUND OF THE INVENTION

1. Field of the Invention

The present invention relates to technology for non-volatile storage.

2. Description of the Related Art

Semiconductor memory devices have become more popular for use in various electronic devices. For example, non-volatile semiconductor memory is used in cellular telephones, digital cameras, personal digital assistants, mobile computing devices, non-mobile computing devices and other devices. Electrical Erasable Programmable Read Only Memory (EEPROM) and flash memory are among the most popular non-volatile semiconductor memories.

Both EEPROM and flash memory utilize a floating gate that is positioned above and insulated from a channel region in a semiconductor substrate. The floating gate is positioned between source and drain regions. A control gate is provided over and insulated from the floating gate. The threshold voltage of the transistor is controlled by the amount of charge that is retained on the floating gate. That is, the minimum amount of voltage that must be applied to the control gate before the transistor is turned on to permit conduction between its source and drain is controlled by the level of charge on the floating gate.

When programming an EEPROM or flash memory device, typically a program voltage is applied to the control gate and the bit line is grounded. Electrons from the channel are injected into the floating gate. When electrons accumulate in the floating gate, the floating gate becomes negatively charged and the threshold voltage of the memory cell is raised so that the memory cell is in the programmed state. More information about programming can be found in U.S. Pat. No. 6,859,397, titled “Source Side Self Boosting Technique For Non-Volatile Memory;” and U.S. Pat. No. 6,917,542, titled “Detecting Over Programmed Memory,” both patents are incorporated herein by reference in their entirety.

Some EEPROM and flash memory devices have a floating gate that is used to store two ranges of charges and, therefore, the memory cell can be programmed/erased between two states, an erased state and a programmed state that correspond to data “1” and data “0.” Such a device is referred to as a binary or two-state device.

A multi-state flash memory cell is implemented by identifying multiple, distinct allowed threshold voltage ranges. Each distinct threshold voltage range corresponds to a predetermined value for the set of data bits. The specific relationship between the data programmed into the memory cell and the threshold voltage ranges of the memory cell depends upon the data encoding scheme adopted for the memory cells. For example, U.S. Pat. No. 6,222,762 and U.S. Patent Application Publication No. 2004/0255090, both of which are incorporated herein by reference in their entirety, describe various data encoding schemes for multi-state flash memory cells.

Typically, the program voltage (Vpgm) is applied to the control gates of the memory cells as a series of pulses. The magnitude of the pulses is increased with each successive pulse by a predetermined step size (e.g. 0.2v, 0.3v, 0.4v, or others). In the periods between the pulses, verify operations are carried out. That is, the programming level of each memory cell of a group of memory cells being programmed in parallel is sensed between each programming pulse to determine whether it is equal to or greater than a verify level to which it is being programmed. One means of verifying the programming is to test conduction at a specific compare threshold voltage point. The memory cells that are verified to be sufficiently programmed are locked out, for example, by raising the bit line voltage to stop the programming process for those memory cells. The above described techniques, and others described herein, can be used in combination with various boosting techniques to prevent program disturb and with various efficient verify techniques known in the art.

In some embodiments of a flash memory system, the smallest portion of data that can be separately written to the flash memory is defined as a “page.” The bits of a single multi-state flash memory cell may all belong to the same flash page, or they may be assigned to different pages so that, for example in a 3-bit cell, the lowest bit is in page 0, the middle bit is in page 1, the upper bit in page 2. Each of the pages containing the lower bits, the middle bits or the upper bits will be referred to as a logical page.

Flash memory system use Error Correction Codes (ECC) for ensuring the reliability of the data stored in the system. During encoding, parity bits are added to the information bits to form code words. The code words are stored in the flash memory using the programming process. During reading, the representation of the code words are decoded into code words to identify the underlying data. Errors of individual bits in a representation of a code word are corrected up to a certain correction capability of the code. The use of ECC with storage of data is well known in the art.

A common embodiment for a process of reading the contents of memory cells consists of comparisons of the memory cell threshold voltage with fixed reference voltages (also known as read compare levels). The number of reference voltages (read compare levels) is one less than the number of programmed states. However, U.S. Pat. No. 6,751,766, incorporated herein by reference in its entirety, provides an example of the use of more reference voltages than programmed states to estimate the reliability of read bits.

A high performance low-complexity coding scheme using an advanced Low Density Parity Check (LDPC) code is known for use with storing data in non-volatile memories. LDPC codes can be decoded using iterative message passing decoding algorithms. These algorithms operate by exchanging messages between variable and check nodes over the edges of an underlying bipartite graph representing the code. The decoder is provided with initial estimates of the stored bits based on the voltage levels read from the memory cells. These initial estimates are refined and improved by imposing the parity-check constraints that the bits should satisfy as a valid codeword. These initial estimates are then updated through exchange of information between the variable nodes representing the code word bits and the check nodes representing parity-check constraints on the code word bits.

The initial estimates used in LDPC decoding include hard bits and soft bits. Hard bits are an estimate of the actual data being stored. For example, hard bits are generally created by sensing the memory cells threshold voltage at the read compare levels. Soft bits are extra information from sensing at voltage levels other than the read compare levels. It is known in the art to use hard bits and soft bits to decode information sensed from memory cells. For example, more information about the LDPC decoding can be found in the following patent documents, all of which are incorporated herein by reference: U.S. Pat. No. 8,099,652; U.S. Pat. No. 8,059,463; U.S. Patent Application Publication No. 2011/0205823; U.S. Patent Application Publication No. 2007/0283227; U.S. Patent Application Publication No. 2011/0252283; U.S. Pat. No. 7,814,401; U.S. Pat. No. 7,966,546; U.S. Pat. No. 7,966,550; U.S. Pat. No. 7,797,480; U.S. Pat. No. 7,904,793;

Although using soft bits can improve the accuracy of the read process, the extra sensing to obtain the soft bits can slow down the read process.

### BRIEF DESCRIPTION OF THE DRAWINGS

FIG. 1A is a top view of a NAND string.

FIG. 1B is an equivalent circuit diagram of the NAND string.

FIG. 2 depicts a cross section of an example NAND string.

FIG. 3 is a block diagram of a non-volatile memory system.

FIG. 4 is a block diagram depicting one embodiment of a sense block.

FIG. 4A shows an example implementation of data latches.

FIG. 5 is a block diagram depicting one embodiment of a memory array.

FIG. 6 is a flow chart describing one embodiment of a process for programming.

FIG. 7 is a flow chart describing one embodiment of a process for programming data into a block of memory cells.

FIG. 8 depicts an example set of threshold voltage distributions and describes a process for programming non-volatile memory.

FIG. 9 depicts three programming pulses, and the verify pulses applied between the programming pulses.

FIGS. 10A-E show various threshold voltage distributions and describe a process for programming non-volatile memory.

FIG. 11 is a flow chart describing one embodiment of a process for programming non-volatile memory.

FIG. 12 show threshold distributions for memory cells with compare voltages for hard bits and soft bits.

FIG. 13 show threshold distributions for memory cells with example compare voltages for hard bits and soft bits.

FIG. 14 is a flow chart describing one embodiment of a process for reading hard bits and soft bits.

FIG. 15 is a timing diagram showing one embodiment of a sensing operation.

FIG. 16 is a flow chart describing one embodiment of a process for sensing information for hard bits and soft bits.

FIGS. 17A-D show the contents of registers during on example of a read process.

FIGS. 18A and B show a plots of voltage versus time for a sense node in a sense amplifier.

FIG. 19 is a flow chart describing one embodiment of a process for reading hard bits and soft bits.

FIG. 20 is a flow chart describing one embodiment of a process for sensing information for hard bits.

FIG. 21 is a flow chart describing one embodiment of a process for sensing information for soft bits.

FIG. 22 is a timing diagram showing one embodiment of a sensing operation.

FIG. 23 show threshold distributions for memory cells with example compare voltages for hard bits and soft bits.

FIG. 24 is a flow chart describing one embodiment of a process for sensing information for soft bits.

FIG. 25 show threshold distributions for memory cells with example compare voltages for hard bits and soft bits.

FIG. 26 is a flow chart describing one embodiment of a process for reading hard bits and soft bits.

FIG. 27 is a flow chart describing one embodiment of a process for reading hard bits and soft bits.

FIG. 28 is a flow chart describing one embodiment of a process for sensing information for soft bits.

FIG. 29 is a flow chart describing one embodiment of a process for sensing information for soft bits.

FIG. 30 show threshold distributions for memory cells with example compare voltages for hard bits and soft bits.

### DETAILED DESCRIPTION

A system is disclosed for jointly reading hard bit information and soft bit information from non-volatile storage. Some of the hard bit information and/or soft bit information is read concurrently by using different bit line voltages, different integration times, different sense levels within the sense amplifiers, or other techniques. A method is also disclosed for determining the hard bits and soft bits in real time based on the sensed hard bit information and soft bit information.

The technology described herein allows the hard bits and soft bits to be read faster than in previous systems. The use of soft bits will increase the accuracy of the read process. Therefore, the technology described herein allows for a fast and accurate read process.

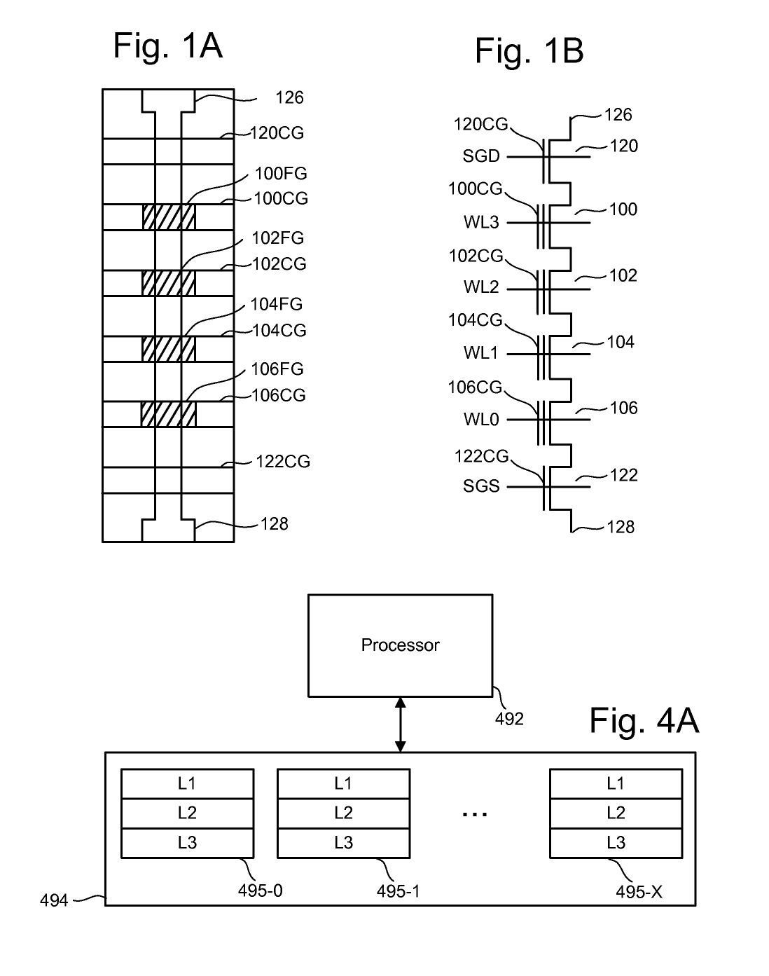

One example of a non-volatile storage system that can implement the technology described herein is a flash memory system that uses the NAND structure, which includes arranging multiple transistors in series, sandwiched between two select gates. The transistors in series and the select gates are referred to as a NAND string. FIG. 1A is a top view showing one NAND string. FIG. 1B is an equivalent circuit thereof. The NAND string depicted in FIGS. 1A and 1B includes four transistors 100, 102, 104 and 106 in series and sandwiched between (drain side) select gate 120 and (source side) select gate 122. Select gate 120 connects the NAND string to a bit line via bit line contact 126. Select gate 122 connects the NAND string to source line 128. Select gate 120 is controlled by applying the appropriate voltages to select line SGD. Select gate 122 is controlled by applying the appropriate voltages to select line SGS. Each of the transistors 100, 102, 104 and 106 has a control gate and a floating gate. For example, transistor 100 has control gate 100CG and floating gate 100FG. Transistor 102 includes control gate 102CG and a floating gate 102FG. Transistor 104 includes control gate 104CG and floating gate 104FG. Transistor 106 includes a control gate 106CG and a floating gate 106FG. Control gate 100CG is connected to word line WL3, control gate 102CG is connected to word line WL2, control gate 104CG is connected to word line WL1, and control gate 106CG is connected to word line WL0.

Note that although FIGS. 1A and 1B show four memory cells in the NAND string, the use of four memory cells is only provided as an example. A NAND string can have less than four memory cells or more than four memory cells. For example, some NAND strings will have 128 memory cells or more. The discussion herein is not limited to any particular number of memory cells in a NAND string. One embodiment uses NAND strings with 66 memory cells, where 64 memory cells are used to store data and two of the memory cells are referred to as dummy memory cells because they do not store data.

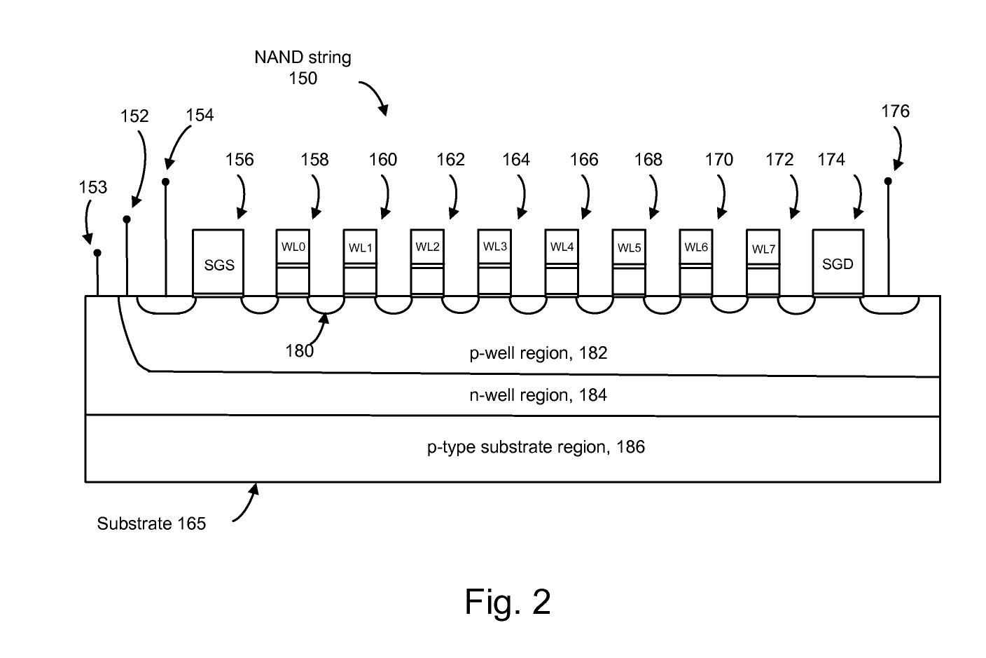

FIG. 2 depicts a cross-sectional view of a NAND string formed on a substrate. The view is simplified and not to scale. The NAND string 150 includes a source-side select gate 156, a drain-side select gate 174, and eight storage elements 158, 160, 162, 164, 166, 168, 170 and 4172, formed on a substrate 165. A number of source/drain regions, one example of which is source/drain region 180, are provided on either side of each storage element and the select gates 156 and 174.

In one approach, the substrate 165 employs a triple-well technology which includes a p-well region 182 within an n-well region 184, which in turn is within a p-type substrate region 186. The NAND string and its non-volatile storage elements can be formed, at least in part, on the p-well region. A source supply line 154 is provided in addition to a bit line 426. Voltages, such as body bias voltages, can also be applied to the p-well region '82 via a terminal '52 and/or to the n-well region 184 via a terminal 153.

A typical architecture for a flash memory system using a NAND structure will include several NAND strings. Each NAND string is connected to the common source line by its source select gate controlled by select line SGS and connected to its associated bit line by its drain select gate controlled by select line SGD. Each bit line and the respective NAND string(s) that are connected to that bit line via a bit line contact comprise the columns of the array of memory cells. Bit lines are shared with multiple NAND strings. Typically, the bit line runs on top of the NAND strings in a direction perpendicular to the word lines and is connected to a sense amplifier.

Relevant examples of NAND type flash memories and their operation are provided in the following U.S. patents/patent applications, all of which are incorporated herein by reference in their entirety: U.S. Pat. No. 5,570,315; U.S. Pat. No. 5,774,397; U.S. Pat. No. 6,046,935; U.S. Pat. No. 6,456,528; and U.S. Pat. Publication No. US2003/0002348.

Other types of non-volatile storage devices, in addition to NAND flash memory, can also be used to implement the new technology described herein. For example, a TANOS structure (consisting of a stacked layer of TaN—Al₂O₃—SiN—SiO₂ on a silicon substrate), which is basically a memory cell using trapping of charge in a nitride layer (instead of a floating gate), can also be used with the technology described herein. Another type of memory cell useful in flash EEPROM systems utilizes a non-conductive dielectric material in place of a conductive floating gate to store charge in a non-volatile manner. Such a cell is described in an article by Chan et al., “A True Single-Transistor Oxide-Nitride-Oxide EEPROM Device,” IEEE Electron Device Letters, Vol. EDL-8, No. 3, March 1987, pp. 93-95. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. See also Nozaki et al., “A 1-Mb EEPROM with MONOS Memory Cell for Semiconductor Disk Application,” IEEE Journal of Solid-State Circuits, Vol. 26, No. 4, April 1991, pp. 497-501, which describes a similar cell in a split-gate configuration where a doped polysilicon gate extends over a portion of the memory cell channel to form a separate select transistor.

Another example is described by Eitan et al., “NROM: A Novel Localized Trapping, 2-Bit Nonvolatile Memory Cell,” IEEE Electron Device Letters, vol. 21, no. 11, November 2000, pp. 543-545. An ONO dielectric layer extends across the channel between source and drain diffusions. The charge for one data bit is localized in the dielectric layer adjacent to the drain, and the charge for the other data bit is localized in the dielectric layer adjacent to the source. U.S. Pat. Nos. 5,768,192 and 6,011,725 disclose a non-volatile memory cell having a trapping dielectric sandwiched between two silicon dioxide layers. Multi-state data storage is implemented by separately reading the binary states of the spatially separated charge storage regions within the dielectric. Other types of non-volatile memory technologies can also be used.

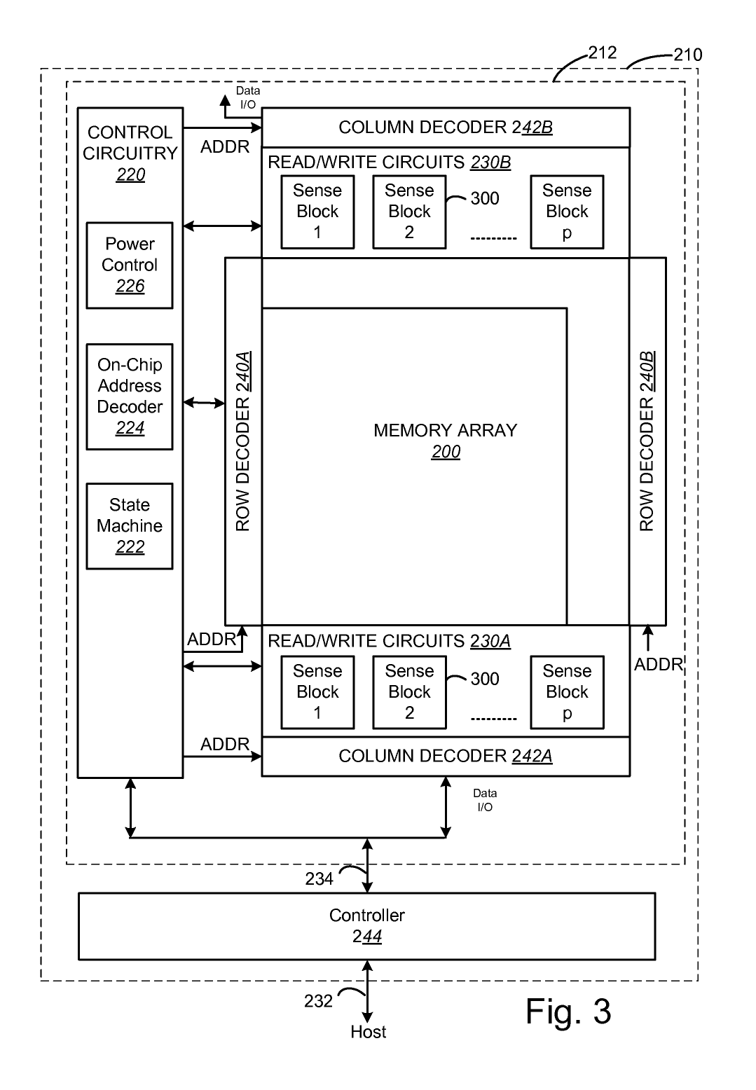

FIG. 3 illustrates a memory device 210 having read/write circuits for reading and programming a page of memory cells (e.g., NAND multi-state flash memory) in parallel. Memory device 210 may include one or more memory die or chips 212. Memory die 212 includes an array (two-dimensional or three dimensional) of memory cells 200, control circuitry 220, and read/write circuits 230A and 230B. In one embodiment, access to the memory array 200 by the various peripheral circuits is implemented in a symmetric fashion, on opposite sides of the array, so that the densities of access lines and circuitry on each side are reduced by half. The read/write circuits 230A and 230B include multiple sense blocks 300 which allow a page of memory cells to be read or programmed in parallel. The memory array 200 is addressable by word lines via row decoders 240A and 240B and by bit lines via column decoders 242A and 242B. In a typical embodiment, a controller 244 is included in the same memory device 210 (e.g., a removable storage card or package) as the one or more memory die 212. Commands and data are transferred between the host and controller 244 via lines 232 and between the controller and the one or more memory die 212 via lines 234. Some memory systems may include multiple dies 212 in communication with Controller 244.

Control circuitry 220 cooperates with the read/write circuits 230A and 230B to perform memory operations on the memory array 200. The control circuitry 220 includes a state machine 222, an on-chip address decoder 224 and a power control module 226. The state machine 222 provides chip-level control of memory operations. The on-chip address decoder 224 provides an address interface between that used by the host or a memory controller to the hardware address used by the decoders 240A, 240B, 242A, and 242B. The power control module 226 controls the power and voltages supplied to the word lines and bit lines during memory operations. In one embodiment, power control module 226 includes one or more charge pumps that can create voltages larger than the supply voltage. Control circuitry 220, power control 226, decoder 224, state machine 222, decoders 240 A/B & 242A/B, the read/write circuits 230A/B and the controller 244, collectively or separately, can be referred to as one or more control circuits. Of the one or more control circuits, power control 226, decoder 224, state machine 222, decoders 240 A/B & 242A/B, and the read/write circuits 230A/B are on-memory circuits since they are located on memory die 212.

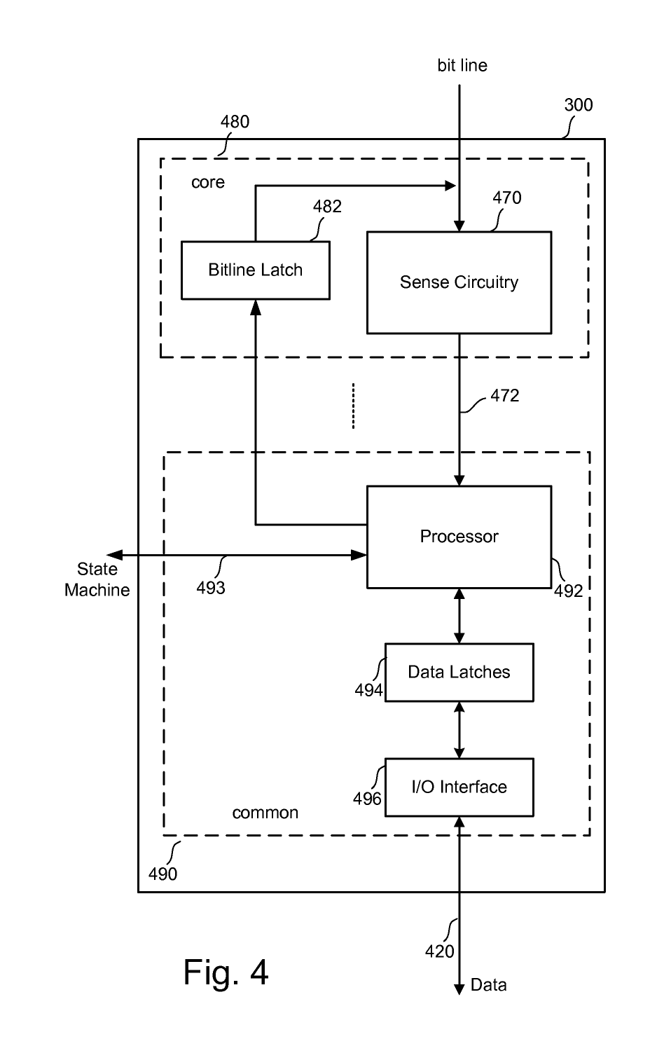

FIG. 4 is a block diagram of an individual sense block 300 partitioned into a core portion, referred to as a sense module 480, and a common portion 490. In one embodiment, there will be a separate sense module 480 for each bit line and one common portion 490 for a set of multiple sense modules 480. In one example, a sense block will include one common portion 490 and eight sense modules 480. Each of the sense modules in a group will communicate with the associated common portion via a data bus 472. For further details, refer to U.S. Patent Application Publication 2006/0140007, which is incorporated herein by reference in its entirety.

Sense module 480 comprises sense circuitry 470 that determines whether a conduction current in a connected bit line is above or below a predetermined level. In some embodiments, sense module 480 includes a circuit commonly referred to as a sense amplifier. Sense module 480 also includes a bit line latch 482 that is used to set a voltage condition on the connected bit line. For example, a predetermined state latched in bit line latch 482 will result in the connected bit line being pulled to a state designating program inhibit (e.g., Vdd).

Common portion 490 comprises a processor 492, a set of data latches 494 and an I/O Interface 496 coupled between the set of data latches 494 and data bus 420. Processor 492 performs computations. For example, one of its functions is to determine the data stored in the sensed memory cell and store the determined data in the set of data latches. The set of data latches 494 is used to store data bits determined by processor 492 during a read operation. It is also used to store data bits imported from the data bus 420 during a program operation. The imported data bits represent write data meant to be programmed into the memory. I/O interface 496 provides an interface between data latches 494 and the data bus 420.

During read or sensing, the operation of the system is under the control of state machine 222 that controls the supply of different control gate voltages to the addressed cell. As it steps through the various predefined control gate voltages (the read reference voltages or the verify reference voltages) corresponding to the various memory states supported by the memory, the sense module 480 may trip at one of these voltages and an output will be provided from sense module 480 to processor 492 via bus 472. At that point, processor 492 determines the resultant memory state by consideration of the tripping event(s) of the sense module and the information about the applied control gate voltage from the state machine via input lines 493. It then computes a binary encoding for the memory state and stores the resultant data bits into data latches 494. In another embodiment of the core portion, bit line latch 482 serves double duty, both as a latch for latching the output of the sense module 480 and also as a bit line latch as described above.

It is anticipated that some implementations will include multiple processors 492. In one embodiment, each processor 492 will include an output line (not depicted in FIG. 4) such that each of the output lines is wired-OR'd together. In some embodiments, the output lines are inverted prior to being connected to the wired-OR line. This configuration enables a quick determination during the program verification process of when the programming process has completed because the state machine receiving the wired-OR line can determine when all bits being programmed have reached the desired level. For example, when each bit has reached its desired level, a logic zero for that bit will be sent to the wired-OR line (or a data one is inverted). When all bits output a data 0 (or a data one inverted), then the state machine knows to terminate the programming process. In embodiments where each processor communicates with eight sense modules, the state machine may (in some embodiments) need to read the wired-OR line eight times, or logic is added to processor 492 to accumulate the results of the associated bit lines such that the state machine need only read the wired-OR line one time. In some embodiments that have many sense modules, the wired-OR lines of the many sense modules can be grouped in sets of N sense modules, and the groups can then be grouped to form a binary tree.

During program or verify, the data to be programmed is stored in the set of data latches 494 from the data bus 420. The program operation, under the control of the state machine, comprises a series of programming voltage pulses (with increasing magnitudes) concurrently applied to the control gates of the addressed memory cells to that the memory cells are programmed at the same time. Each programming pulse is followed by a verify process to determine if the memory cell has been programmed to the desired state. Processor 492 monitors the verified memory state relative to the desired memory state. When the two are in agreement, processor 492 sets the bit line latch 482 so as to cause the bit line to be pulled to a state designating program inhibit. This inhibits the memory cell coupled to the bit line from further programming even if it is subjected to programming pulses on its control gate. In other embodiments the processor initially loads the bit line latch 482 and the sense circuitry sets it to an inhibit value during the verify process.

Data latch stack 494 contains a stack of data latches corresponding to the sense module. In one embodiment, there are three (or four or another number) data latches per sense module 480. In some implementations (but not required), the data latches are implemented as a shift register so that the parallel data stored therein is converted to serial data for data bus 420, and vice versa. In one preferred embodiment, all the data latches corresponding to the read/write block of memory cells can be linked together to form a block shift register so that a block of data can be input or output by serial transfer. In particular, the bank of read/write modules is adapted so that each of its set of data latches will shift data into or out of the data bus in sequence as if they are part of a shift register for the entire read/write block.

FIG. 4A shows an example implementation of data latches 494, including a set of latches 495-0, 495-1, . . . , 495-X for each bit line. Each set of latches includes three latches L1, L2 and L3. In other embodiments, each set of latches has more or less than three latches.

Additional information about the structure and/or operations of various embodiments of non-volatile storage devices can be found in (1) United States Patent Application Pub. No. 2004/0057287, “Non-Volatile Memory And Method With Reduced Source Line Bias Errors,” published on Mar. 25, 2004; (2) United States Patent Application Pub No. 2004/0109357, “Non-Volatile Memory And Method with Improved Sensing,” published on Jun. 10, 2004; (3) U.S. Patent Application Pub. No. 20050169082; (4) U.S. Patent Application Pub. 2006/0221692, titled “Compensating for Coupling During Read Operations of Non-Volatile Memory,” Inventor Jian Chen, filed on Apr. 5, 2005; and (5) U.S. Patent Application Pub. 2006/0158947, titled “Reference Sense Amplifier For Non-Volatile Memory, Inventors Siu Lung Chan and Raul-Adrian Cernea, filed on Dec. 28, 2005. All five of the immediately above-listed patent documents are incorporated herein by reference in their entirety.

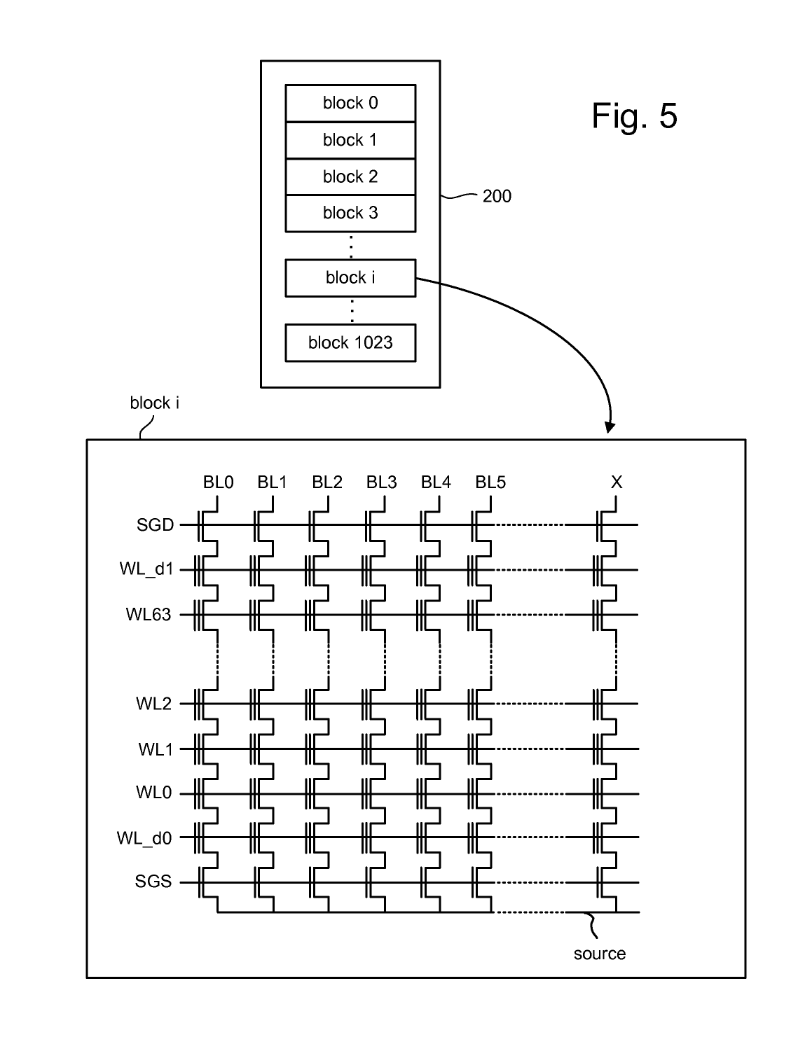

FIG. 5 depicts an exemplary structure of memory cell array 200. In one embodiment, the array of memory cells is divided into a large number of blocks of memory cells. As is common for flash EEPROM systems, the block is the unit of erase. That is, each block contains the minimum number of memory cells that are erased together. Other embodiments can use different units of erase.

FIG. 5 also shows more details of block i of memory array 200. Block i includes X+1 bit lines and X+1 NAND strings. Block i also includes 64 data word lines (WL0-WL63), 2 dummy word lines (WL_d0 and WL_d1), a drain side select line (SGD) and a source side select line (SGS). One terminal of each NAND string is connected to a corresponding bit line via a drain select gate (connected to select line SGD), and another terminal is connected to the source line via a source select gate (connected to select line SGS). Because there are sixty four data word lines and two dummy word lines, each NAND string includes sixty four data memory cells and two dummy memory cells. In other embodiments, the NAND strings can have more or fewer than 64 data memory cells and more or fewer dummy memory cells. Data memory cells can store user or system data. Dummy memory cells are typically not used to store user or system data. Some embodiments do not include dummy memory cells.

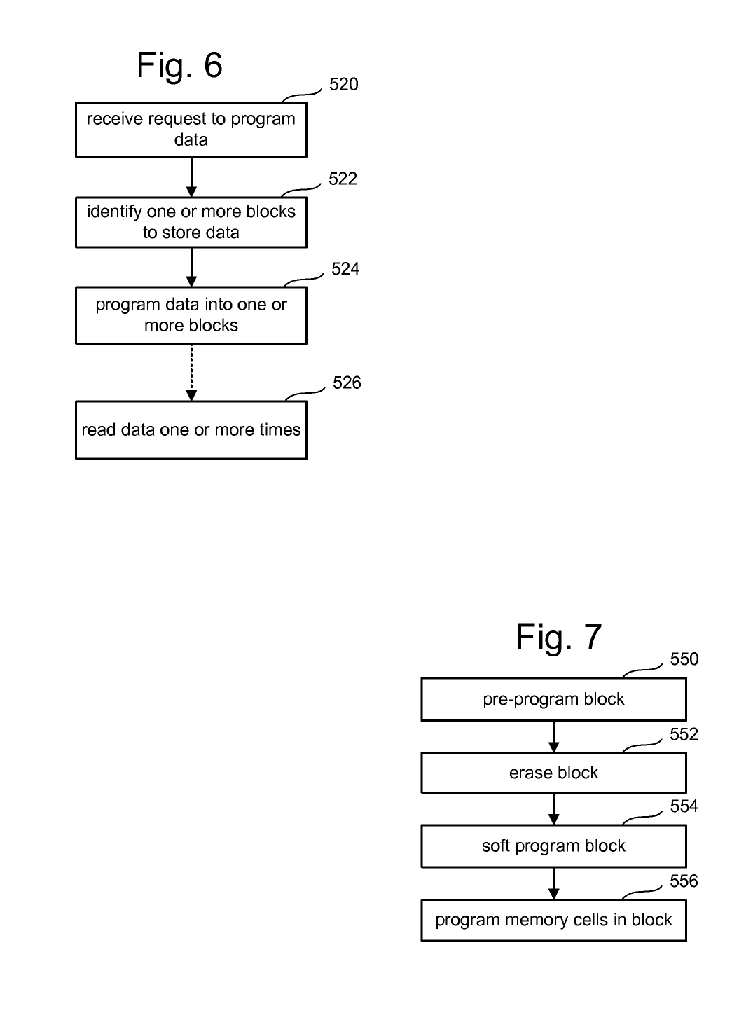

FIG. 6 is a flow chart describing one embodiment of a process for operating a non-volatile storage system. In step 520, a request for programming is received from the Host, the Controller or other entity. In step 522, the Controller (or state machine or other entity) will determine which set of one or more blocks to store the data. In step 524, the data received for the request is programmed into one or more blocks of memory cells. In step 526, the data can be read. The dashed line between steps 524 and 526 indicates that there can be an unpredictable amount of time between programming and reading.

FIG. 7 is a flow chart describing a process for programming a block of memory. The process of FIG. 7 is performed one or more times during step 524 of FIG. 6. In one example implementation, memory cells are pre-programmed in order to maintain even wear on the memory cells (step 550). In one embodiment, the memory cells are preprogrammed to the highest data state, a random pattern, or any other pattern. In some implementations, pre-programming need not be performed. Some embodiments do not implement pre-programming.

In step 552, memory cells are erased (in blocks or other units) prior to programming. Memory cells are erased in one embodiment by raising the p-well to an erase voltage (e.g., 20 volts) for a sufficient period of time and grounding the word lines of a selected block while the source and bit lines are floating. In blocks that are not selected to be erased, word lines are floated. Due to capacitive coupling, the unselected word lines, bit lines, select lines, and the common source line are also raised to a significant fraction of the erase voltage thereby impeding erase on blocks that are not selected to be erased. In blocks that are selected to be erased, a strong electric field is applied to the tunnel oxide layers of selected memory cells and the selected memory cells are erased as electrons of the floating gates are emitted to the substrate side, typically by Fowler-Nordheim tunneling mechanism. As electrons are transferred from the floating gate to the p-well region, the threshold voltage of a selected cell is lowered. Erasing can be performed on the entire memory array, on individual blocks, or another unit of memory cells. In one embodiment, after erasing the memory cells, all of the erased memory cells in the block will be in state S0 (discussed below). One implementation of an erase process includes applying several erase pulses to the p-well and verifying between erase pulses whether the NAND strings are properly erased.

In step 554, soft programming is (optionally) performed to narrow the distribution of erased threshold voltages for the erased memory cells. Some memory cells may be in a deeper erased state than necessary as a result of the erase process. Soft programming can apply programming pulses to move the threshold voltage of the deeper erased memory cells to the erase threshold distribution. In step 556, the memory cells of the block are programmed. The programming can be performed in response to a request to program from the host, or in response to an internal process. After programming, the memory cells of the block can be read. Many different read processes known in the art can be used to read data. In some embodiments, the read process includes using ECC to correct errors. The data that is read is output to the hosts that requested the read operation. The ECC process can be performed by the state machine, the controller or another device. The erase-program cycle can happen many times without or independent of reading, the read process can occur many times without or independent of programming and the read process can happen any time after programming. The process of FIG. 7 can be performed at the direction of the state machine using the various circuits described above. In other embodiments, the process of FIG. 7 can be performed at the direction of the Controller using the various circuits described above.

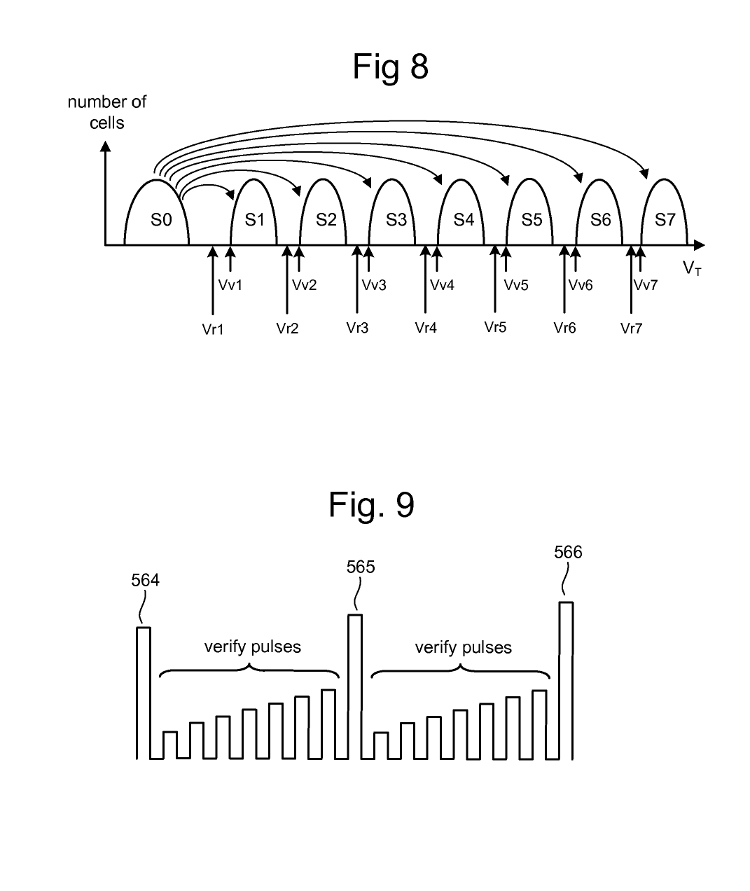

At the end of a successful programming process (with verification), the threshold voltages of the memory cells should be within one or more distributions of threshold voltages for programmed memory cells or within a distribution of threshold voltages for erased memory cells, as appropriate. FIG. 8 illustrates example threshold voltage distributions for the memory cell array when each memory cell stores three bits of data. Other embodiments, however, may use more or less than three bits of data per memory cell (e.g., such as three bits of data per memory cell).

In the example of FIG. 8, each memory cell stores three bits of data; therefore, there are eight valid threshold voltage distributions, also called data states: S0, S1, S2, S3, S4, S5, S6 and S7. In one embodiment, data state S0 is below 0 volts and data states S1-S7 are above 0 volts. In other embodiments, all eight data states are above 0 volts, or other arrangements can be implemented. In one embodiment, the threshold voltage distribution for S0 is wider than for S1-S7. In one embodiment, S0 is for erased memory cells. Data is programmed from S0 to S1-S7.

Each data state corresponds to a unique value for the three data bits stored in the memory cell. In one embodiment, S0=111, S1=110, S2=101, S3=100, S4=011, S5=010, S6=001 and S7=000. Other mapping of data to states S0-S7 can also be used. The specific relationship between the data programmed into the memory cell and the threshold voltage levels of the cell depends upon the data encoding scheme adopted for the cells. For example, U.S. Pat. No. 6,222,762 and U.S. Patent Application Publication No. 2004/0255090, “Tracking Cells For A Memory System,” filed on Jun. 13, 2003, both of which are incorporated herein by reference in their entirety, describe various data encoding schemes for multi-state flash memory cells. In one embodiment, data values are assigned to the threshold voltage ranges using a Gray code assignment so that if the threshold voltage of a floating gate erroneously shifts to its neighboring threshold voltage distribution, only one bit will be affected. However, in other embodiments, Gray code is not used.

In one embodiment, all of the bits of data stored in a memory cell are stored in the same logical page. In other embodiments, each bit of data stored in a memory cell corresponds to different logical pages. Thus, a memory cell storing three bits of data would include data in a first page, data in a second page and data in a third page. In some embodiments, all of the memory cells connected to the same word line would store data in the same three pages of data. In some embodiments, the memory cells connected to a word line can be grouped into different sets of pages (e.g., by odd and even bit lines, or by other arrangements).

In some devices, the memory cells will be erased to state S0. From state S0, the memory cells can be programmed to any of states S1-S7. In one embodiment, known as full sequence programming, memory cells can be programmed from the erased state S0 directly to any of the programmed states S1-S7. For example, a population of memory cells to be programmed may first be erased so that all memory cells in the population are in erased state S0. While some memory cells are being programmed from state S0 to state S1, other memory cells are being programmed from state S0 to state S2, state S0 to state S3, state S0 to state S4, state S0 to state S5, state S0 to state S6, and state S0 to state S7. Full sequence programming is graphically depicted by the seven curved arrows of FIG. 8.

FIG. 8 shows a set of verify target levels Vv1, Vv2, Vv3, Vv4, Vv5, Vv6, and Vv7. These verify levels are used as comparison levels (also known as target levels) during the programming process. For example, when programming memory cells to state S1, the system will check to see if the threshold voltages of the memory cells have reached Vv1. If the threshold voltage of a memory cell has not reached Vv1, then programming will continue for that memory cell until its threshold voltage is greater than or equal to Vv1. If the threshold voltage of a memory cell has reached Vv1, then programming will stop for that memory cell. Verify target level Vv2 is used for memory cells being programmed to state S2. Verify target level Vv3 is used for memory cells being programmed to state S3. Verify target level Vv4 is used for memory cells being programmed to state S4. Verify target level Vv5 is used for memory cells being programmed to state S5. Verify target level Vv6 is used for memory cells being programmed to state S6. Verify target level Vv7 is used for memory cells being programmed to state S7.

FIG. 8 also shows a set of read compare levels Vr1, Vr2, Vr3, Vr4, Vr5, Vr6, and Vr7. These read compare levels are used as comparison levels during the read process. By testing whether the memory cells turn on or remain off in response to the read compare levels Vr1, Vr2, Vr3, Vr4, Vr5, Vr6, and Vr7 being separately applied to the control gates of the memory cells, the system can determine which states that memory cells are storing data for.

In general, during verify operations and read operations, the selected word line is connected to a voltage, a level of which is specified for each read operation (e.g., see read compare levels Vr1, Vr2, Vr3, Vr4, Vr5, Vr6, and Vr7, of FIG. 8) or verify operation (e.g. see verify target levels Vv1, Vv2, Vv3, Vv4, Vv5, Vv6, and Vv7 of FIG. 8) in order to determine whether a threshold voltage of the concerned memory cell has reached such level. After applying the word line voltage, the conduction current of the memory cell is measured to determine whether the memory cell turned on in response to the voltage applied to the word line. If the conduction current is measured to be greater than a certain value, then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected memory cells are provided with one or more read pass voltages at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. More information about verifying/reading can be found in the following patent documents that are incorporated herein by reference in their entirety: (1) United States Patent Application Pub. No. 2004/0057287; (2) United States Patent Application Pub No. 2004/0109357; (3) U.S. Patent Application Pub. No. 2005/0169082; and (4) U.S. Patent Application Pub. No. 2006/0221692. The read and verify operations described above are performed according to techniques known in the art. Thus, many of the details explained can be varied by one skilled in the art. Other read and verify techniques known in the art can also be used.

In some embodiments, the program voltage applied to the control gate includes a series of pulses that are increased in magnitude with each successive pulse by a predetermined step size (e.g. 0.2v, 0.3v, 0.4v, or others). Between pulses, some memory systems will verify whether the individual memory cells have reached their respective target threshold voltage ranges. For example, FIG. 9 shows a portion of a signal applied to the control gates of a plurality of memory cells connected to a common word line. FIG. 9 shows programming pulses 564, 565 and 566, with a set of verify pulses between the programming pulses. When performing full sequence programming in one embodiment, the verification process between programming pulses will test for each of the threshold voltage distribution (data states) S1-S7. Therefore, FIG. 9 shows seven verify pulses that have magnitudes corresponding to verify target levels Vv1, Vv2, Vv3, Vv4, Vv5, Vv6, and Vv7. In some embodiments, one or more of the verify operations can be skipped (and, therefore one or more of the verify pulses can be skipped) because the verify operation is not necessary or superfluous. For example, if none of the memory cells being programmed according to FIG. 8 have reached Vv2, there is no reason to verify at Vv7. More information about intelligent verification schemes that skip verification for one or more states can be found in the following patent documents which are incorporated herein by reference in their entirety: U.S. Pat. No. 7,073,103; U.S. Pat. No. 7,224,614; U.S. Pat. No. 7,310,255; U.S. Pat. No. 7,301,817; U.S. Patent App. 2004/0109362; and U.S. Patent App. 2009/0147573.

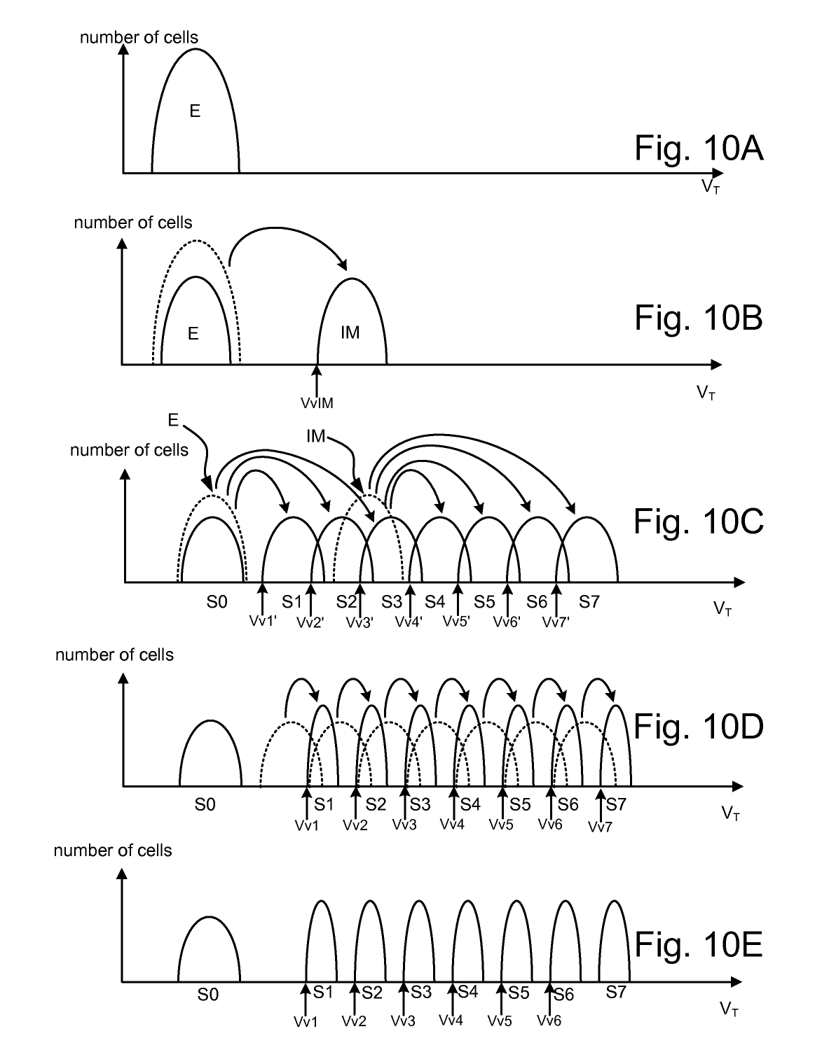

FIG. 8 shows a programming process that includes one phase where all memory cells connected to the same word line are programmed concurrently during that one phase. FIGS. 10A-E illustrates a multi-phase programming approach. In this embodiment, the programming process includes three phases. Prior to programming, the memory cells are erased so that all memory cells connected to a common word line are in an erased threshold voltage distribution E, as depicted in FIG. 10A. During the first phase of programming, those memory cells whose targets (due to the data to be stored in those memory cells) are data states S4, S5, S6 or S7 are programmed to an intermediate state IM. Those memory cells are targeted for data states S0, S1, S2 or S3 and remain in the erased threshold voltage distribution E. The first phase is graphically depicted by FIG. 10B. Memory cells being programmed to intermediate state IM are programmed to a target threshold voltage of VvIM.

During the second phase of the programming process of FIGS. 10A-E, those memory cells that are in the erased threshold voltage distribution E are programmed to their target data states. For example, those memory cells to be programmed to data state S3 are programmed from erased threshold voltage distribution E to data state S3, those memory cells to be programmed to data state S2 are programmed from erased threshold voltage distribution E to data state S2, those memory cells to be programmed to data state S1 are programmed from erase threshold voltage distribution E to data state S1, and those memory cells to be in data state S0 are not programmed during the second phase of the programming process. Thus, erased threshold voltage distribution E becomes data state S0. Also, during the second phase, memory cells are programmed from the intermediate state IM to various data states S4-S7. For example, those memory cells to be programmed to data state S7 are programmed from the intermediate state IM to data state S7, those memory cells targeted to be in data state S6 are programmed from intermediate state IM to data state S6, both memory cells to be programmed to data state S5 are programmed from intermediate state IM to data state S5, and those memory cells to be programmed to data state S4 are programmed from intermediate state IM to data state S4. This second phase of programming is illustrated in FIG. 10C.

As can be seen in FIG. 10C, at the end of the second phase of programming data states S1-S7 overlap with neighboring data states. For example, data state S1 overlaps with data state S2, data state S2 overlaps with data states S1 and S3, data state S3 overlaps with data states S2 and S4, data state S4 overlaps with data states S3 and S5, data state S5 overlaps with data states S4 and S6, and data state S6 overlaps with data states S5 and S7. In some embodiments, all or some of the data states do not overlap.

In the third phase of programming, each of data states S1-S7 are tightened so that they no longer overlap with neighboring states. This is depicted graphically by FIG. 10D. The final result of the three phrase programming process is depicted in step 10E, which shows data states S0-S7. In some embodiments, data state S0 is wider than data states S1-S7.

In some embodiments, those memory cells to be programmed to data state S4 are not programmed during the second phase and, therefore, remain in intermediate state IM. During the third programming phase, the memory cells are programmed from IM to S4. In other embodiments, memory cells destined for other states can also remain in IM or E during the second phase.

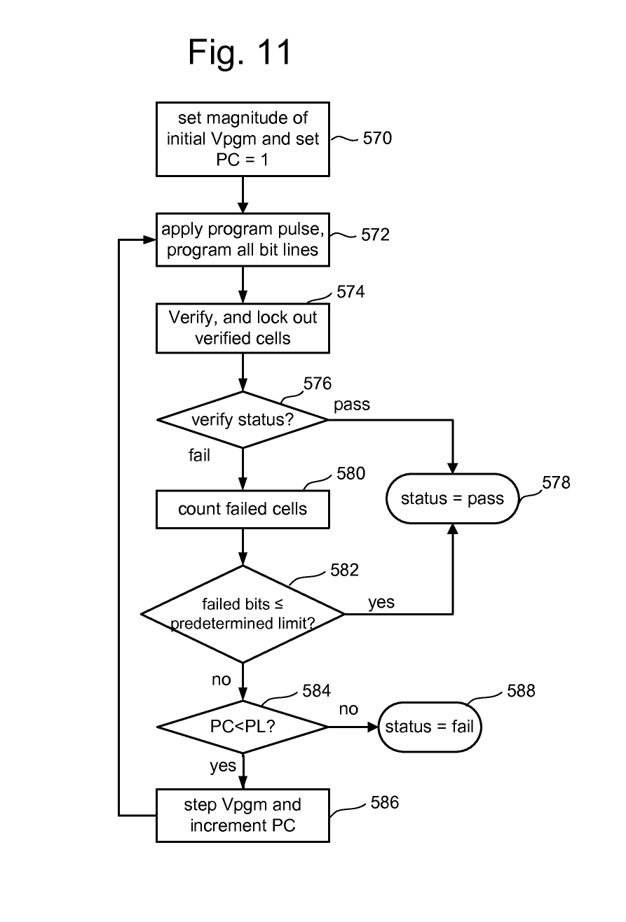

FIG. 11 is a flow chart describing one embodiment of a process for performing programming on memory cells connected to a common word line to one or more targets (e.g., data states or threshold voltage ranges). The process of FIG. 11 can be performed one or multiple times during step 556 of FIG. 7. For example, the process of FIG. 11 can be used to program memory cells (e.g., full sequence programming) from state S0 directly to any of states S1-S7. Alternatively, the process of FIG. 11 can be used to perform one or each of the phases of the process of FIG. 10A-E. For example, when performing the process of FIG. 10A, the process of FIG. 11 is used to implement the first phase that includes programming some of the memory cells from state E to state 1M. The process of FIG. 11 can then be used again to implement the second phase that includes programming some of the memory cells from state E to states S1-S3 and from state IM to states S4-S7. The process of FIG. 11 can be used again to adjust states S1-S7 in the third phase (see FIG. 10D). The process of FIG. 11 can also be used with other multi-phase programming processes.

Typically, the program voltage applied to the control gate during a program operation is applied as a series of program pulses. Between programming pulses are a set of verify pulses to perform verification. In many implementations, the magnitude of the program pulses is increased with each successive pulse by a predetermined step size. In step 570 of FIG. 11, the programming voltage (Vpgm) is initialized to the starting magnitude (e.g., ˜12-16V or another suitable level) and a program counter PC maintained by state machine 222 is initialized at 1. In step 572, a program pulse of the program signal Vpgm is applied to the selected word line (the word line selected for programming). In one embodiment, the group of memory cells being programmed concurrently are all connected to the same word line (the selected word line). The unselected word lines receive one or more boosting voltages (e.g., ˜7-11 volts) to perform boosting schemes known in the art. If a memory cell should be programmed, then the corresponding bit line is grounded. On the other hand, if the memory cell should remain at its current threshold voltage, then the corresponding bit line is connected to Vdd to inhibit programming. In step 572, the program pulse is concurrently applied to all memory cells connected to the selected word line so that all of the memory cells connected to the selected word line are programmed concurrently. That is, they are programmed at the same time (or during overlapping times). In this manner all of the memory cells connected to the selected word line will concurrently have their threshold voltage change, unless they have been locked out from programming.

In step 574, the appropriate memory cells are verified using the appropriate set of target levels to perform one or more verify operations. In one embodiment, the verification process is performed by applying the testing whether the threshold voltages of the memory cells selected for programming have reached the appropriate verify compare voltage (Vv1, Vv2, Vv3, Vv4, Vv5, Vv6, and Vv7).

In step 576, it is determined whether all the memory cells have reached their target threshold voltages (pass). If so, the programming process is complete and successful because all selected memory cells were programmed and verified to their target states. A status of “PASS” is reported in step 578. If, in 576, it is determined that not all of the memory cells have reached their target threshold voltages (fail), then the programming process continues to step 580.

In step 580, the system counts the number of memory cells that have not yet reached their respective target threshold voltage distribution. That is, the system counts the number of cells that have failed the verify process. This counting can be done by the state machine, the controller, or other logic. In one implementation, each of the sense block 300 (see FIG. 3) will store the status (pass/fail) of their respective cells. These values can be counted using a digital counter. As described above, many of the sense blocks have an output signal that is wire-Or'd together. Thus, checking one line can indicate that no cells of a large group of cells have failed verify. By appropriately organizing the lines being wired-Or together (e.g., a binary tree-like structure), a binary search method can be used to determine the number of cells that have failed. In such a manner, if a small number of cells failed, the counting is completed rapidly. If a large number of cells failed, the counting takes a longer time. More information can be found in United States Patent Publication 2008/0126676, incorporated herein by reference in its entirety. In another alternative, each of the sense amplifiers can output an analog voltage or current if its corresponding memory cell has failed and an analog voltage or current summing circuit can be used to count the number of memory cells that have failed.

In one embodiment, there is one total count, which reflects the total number of memory cells currently being programmed that have failed the last verify step. In another embodiment, separate counts are kept for each data state.

In step 582, it is determined whether the count from step 580 is less than or equal to a predetermined limit. In one embodiment, the predetermined limit is the number of bits that can be corrected by ECC during a read process for the page of memory cells. If the number of failed cells is less than or equal to the predetermined limit, than the programming process can stop and a status of “PASS” is reported in step 578. In this situation, enough memory cells programmed correctly such that the few remaining memory cells that have not been completely programmed can be corrected using ECC during the read process. In some embodiments, step 580 will count the number of failed cells for each sector, each target data state or other unit, and those counts will individually or collectively be compared to a threshold in step 582.

In another embodiment, the predetermined limit can be less than the number of bits that can be corrected by ECC during a read process to allow for future errors. When programming less than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed, temperature or other criteria.

If number of failed memory cells is not less than the predetermined limit, than the programming process continues at step 584 and the program counter PC is checked against the program limit value (PL). Examples of program limit values include 20 and 30; however, other values can be used. If the program counter PC is not less than the program limit value PL, then the program process is considered to have failed and a status of FAIL is reported in step 588. If the program counter PC is less than the program limit value PL, then the process continues at step 586 during which time the Program Counter PC is incremented by 1 and the program voltage Vpgm is stepped up to the next magnitude. For example, the next pulse will have a magnitude greater than the previous pulse by a step size (e.g., a step size of 0.1-0.4 volts). After step 586, the process loops back to step 572 and another program pulse is applied to the selected word line.pr

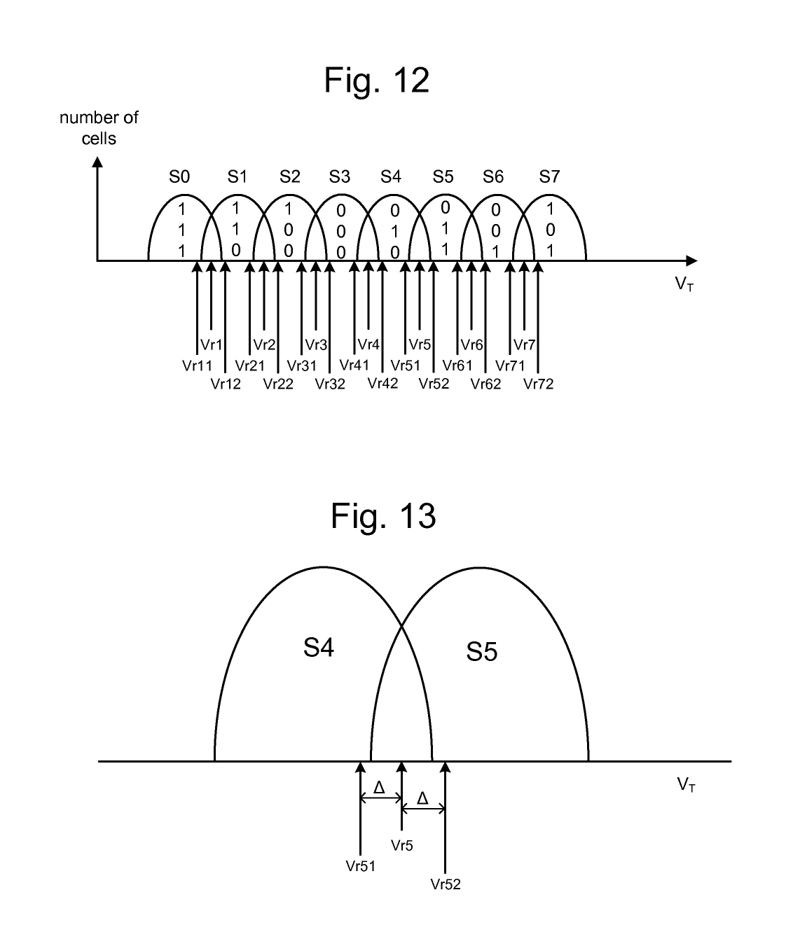

At the end of a programming process (e.g., that includes the method of FIG. 11), the programmed memory cells will be in various data states, such as depicted in FIG. 8. FIG. 8 depicts an ideal threshold voltage distribution, with the data states separated by margins to allow the data to be accurately read. In many actual implementations, due to limitations from programming or from conditions/phenomena after programming, the data states can be overlapping as depicted in FIG. 12. For example, data state S0 overlaps with data state S1, data state S2 overlaps with data states S1 and S3, and so on.

FIG. 12 depicts one example of data encoding. Three bits of data are depicted for each data state. Each bit is in a different logical page. The top bit corresponds to the upper page, the middle bit corresponds to the middle page and the bottom bit corresponds to the lower page. Below is a table that also shows the data encoding for the threshold voltage distribution of FIG. 12.

| | S0 | S1 | S2 | S3 | S4 | S5 | S6 | S7 |
|---|---|---|---|---|---|---|---|---|
| Upper Page | 1 | 1 | 1 | 0 | 0 | 0 | 0 | 1 |
| Middle Page | 1 | 1 | 0 | 0 | 1 | 1 | 0 | 0 |
| Lower Page | 1 | 0 | 0 | 0 | 0 | 1 | 1 | 1 |

FIG. 12 shows the seven read compare voltages Vr1, Vr2, Vr3, Vr4, Vr5, Vr6, and Vr7 discussed above with respect to FIG. 8. While in FIG. 8 the read compare voltages are between (but outside of) the threshold voltage distributions corresponding to the data states, in FIG. 12 the read compare voltages are within the overlap of two neighboring threshold voltage distributions corresponding to data states. As such, a read process that only tests whether the threshold voltages of the memory cells are less than or greater than the seven read compare voltages (e.g., hard bits) may not be accurate enough to correctly read the stored data. Therefore, one set of embodiments will also read one or more soft bits for each data states. The hard bits and the soft bits will be transferred from the memory chip to the Controller. The Controller will use the hard bits and soft bits as part of a LDPC decoding process to accurately determine the data being stored in the memory cells.

FIG. 12 also shows soft bit compare voltages. For example, Vr11 and Vr12 are soft bit compare voltages for one example of a soft bit associated with Vr1. The soft bit for a given memory cell indicates whether that given memory cell has its threshold voltage between Vr11 and Vr12. When reading a memory cell, if Vr1 is applied to the control gate and the memory cell conducts current, then the memory cell is likely to be in state S0. If Vr11 is applied to the control gate and the memory cell conducts, then the Controller has a higher degree of confidence that the memory cell is in state S0. However, if the tests at Vr1 and Vr11 indicate that the threshold voltage of the memory cell is between Vr1 and Vr11, then the Controller has a lower degree of confidence that the memory cell is in state S0. If the threshold voltages is greater than Vr12, then the Controller can be more confident that the memory cell is not in state S0. If the threshold voltage for a memory cell is between Vr1 and Vr12, then the Controller is less confident that the memory cell is not in state S0. This information can be used by the Controller as part of various LDPC decoding processes known in the art. In general, for each read compare voltage (e.g., Vr1, Vr2, . . . ) the memory chip will send to the Controller a hard bit and one or more soft bits to be used as part of the LDPC decoding processes.

FIG. 12 also shows soft bit compare voltages for the other read compare voltages, which are used in the same was as discussed above with respect to Vr11 and Vr12. For example, Vr21 and Vr22 are soft bit compare voltages for one example of a soft bit associated with Vr2. The soft bit for a given memory cell indicates whether that given memory cell has its threshold voltage between Vr21 and Vr22. Vr31 and Vr32 are soft bit compare voltages for one example of a soft bit associated with Vr3. The soft bit for a given memory cell indicates whether that given memory cell has its threshold voltage between Vr31 and Vr32. Vr41 and Vr42 are soft bit compare voltages for one example of a soft bit associated with Vr4. The soft bit for a given memory cell indicates whether that given memory cell has its threshold voltage between Vr41 and Vr42. Vr51 and Vr52 are soft bit compare voltages for one example of a soft bit associated with Vr5. The soft bit for a given memory cell indicates whether that given memory cell has its threshold voltage between Vr51 and Vr52. Vr61 and Vr62 are soft bit compare voltages for one example of a soft bit associated with Vr6. The soft bit for a given memory cell indicates whether that given memory cell has its threshold voltage between Vr61 and Vr62. Vr71 and Vr72 are soft bit compare voltages for one example of a soft bit associated with Vr7. The soft bit for a given memory cell indicates whether that given memory cell has its threshold voltage between Vr71 and Vr72.

In one embodiment, each (or a subset) of the soft bit compare voltages are offset from associated read compare voltage by a fixed amount, referred to below as Δ. For example, FIG. 13 shows Vr51 separated from Vr5 by Δ volts and Vr52 separated from Vr5 by Δ volts.

United States Patent Application 2011/0235420 “Simultaneous Multi-State Read or Verify in Non-Volatile Storage” teaches concurrent reading of memory cells on a word line at different compare voltages, where a first set of the memory cells are sensed using a first comparison voltage concurrently with a second set of memory cells are sensed using a second comparison voltage. One embodiment includes biasing a common source line, biasing a common word line, causing a first bit line voltage to be applied to the first set of the memory cells and causing a second bit line voltage to be applied to the second set of the memory cells. More details can be found in United States Patent Application 2011/0235420, incorporated herein by reference in its entirety.

By applying a read compare voltage to the common word line, having the two bit line voltages differ by 24, threshold voltages for the first set of memory cells can be compared to one soft bit compare voltage and threshold voltages for the second set of memory cells can be compared to another soft bit compare voltage. For example, Vr5 can be applied to the common word line, Vsrc applied to the common source line, Vb1−Δ applied to the first set of bit lines and Vb1+Δ can be applied to the second set of bit lines causing the first set of memory cells to have their threshold voltage tested against Vr51 and the second set of memory cells to have their threshold voltage tested against Vr52. Memory cells who were previously found to conduct in response to Vr5 need only be tested against Vr51 to determine the soft bit since a memory cell that conducts in response to Vr5 must also conduct in response to Vr52. Memory cells who were previously found to not conduct in response to Vr5 need only be tested against Vr52 to determine the soft bit since a memory cell that does not conduct in response to Vr5 must also not conduct in response to Vr51. The same logic applies to the other read compare voltages, including memory systems with more or less than three data bits per memory cell.

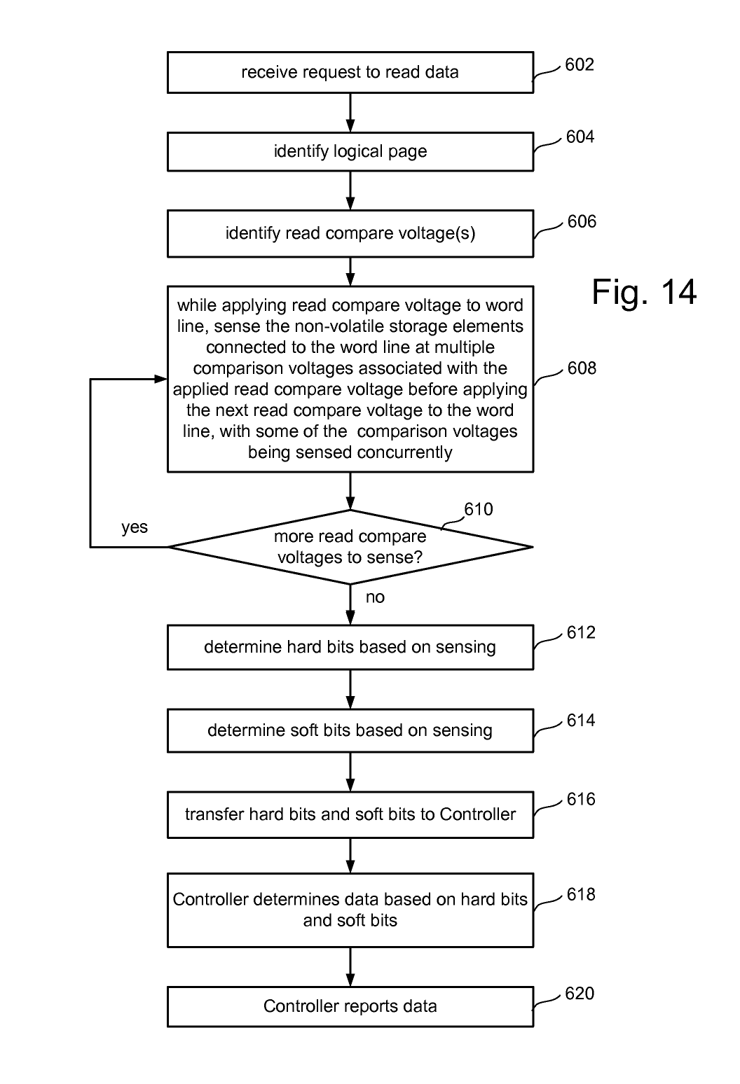

FIG. 14 is a flow chart that describes one embodiment of a process for reading a full logical page, including jointly reading hard bits and soft bits from memory cells. The process includes sensing hard bit information and soft bit information, and determining (and storing) the actual hard bits and soft bits in real time. In embodiment that apply V−Δ and V+Δ, the process can also dynamically determine in real time which bit lines will receive V−Δ and which bit lines will receive V+Δ.

Some embodiments of the process of FIG. 14 include (for a common read process to read a set of data) performing sense operations for a read compare voltage and one or more offsets (e.g., soft bit compare voltages) consecutively (for a subset or all) and concurrently (for a subset or all) before performing sense operations for other read compare voltages. For example, sense operations will be performed by S1, S11 and S12 (all three of which are referred to as comparison voltages) before sensing for S2, S21 or S22 (all three of which are referred to as comparison voltages). Similarly, sense operations will be performed by S2, S21 and S22 before sensing for S3, S31 or S32, and so on. As mentioned, in some embodiments, at least two of the comparison voltages are sensed concurrently (as further described below) in response to a common word line voltage. In this manner, a first subset of the memory cells (non-volatile storage elements) connected to the word line are sensed for a first comparison voltage while a first voltage is applied to bit lines for the first subset of memory cells and a particular word line voltage is applied to the word line and a second subset of the memory cells connected to the word line are sensed for a second comparison voltage while a second voltage is applied to bit lines for the second subset of memory cells and the particular word line voltage is applied to the word line.

In step 602 of FIG. 14, a request to read data is received. The request can be received from a host or other entity. In step 604, one or more logical pages storing the data to be read is identified. As explained above, data can be arranged in logical pages. A Controller may identify the physical location of the data and the logical page for which the data resides. In step 606, the Controller will identify the read compare voltages that need to be used in order to determine the data. For example, looking back at FIG. 12 (in the table above), if the read request is attempting to read the lower page then the Controller would need to perform sense operations at Vr1 and Vr5. If the memory cell turns on in response to Vr1 or does not turn on in response to Vr5, then the data is 1. Otherwise, the data is 0.

If the read request is attempting to read the middle page, then the system must perform sense operations at Vr2, Vr4 and Vr6. If the memory cell turns on in response to Vr2, or does not turn on in response to Vr4 and does turn on in response to Vr6, then the memory cell is storing data 1 in the middle page. Otherwise, the middle page data is 0.

If the read request is attempting to read data in the upper page, then the system will perform sensing operations at Vr3 and Vr7. If the memory cell turns on in response to Vr3 or does not turn on in response to Vr7, then the memory cell is storing data 1. Otherwise, the memory cell is storing data 0.

In step 608 of FIG. 14, one of the identified read compare voltages will be applied to the word line connected to the memory cells being read. In one set of embodiments, the read operation will be performed simultaneously on multiple memory cells connected to a common word line. In step 608, while applying the read compare voltage to the word line, the system will sense the memory cells connected to the word line at multiple comparison voltages associated with the applied read compare voltage before applying the next read compare voltage to the word line. Some of the comparison voltages will be sensed concurrently. For example, looking at FIG. 12, the read compare voltage Vr1 is associated with at least three comparison voltages: Vr1, Vr11 and Vr12.

If there are more read compare voltages that were identified in step 606 that need to be applied (step 610), then the process the loop back to step 608 and apply the next read compare voltage while performing step 608 again. When all the read compare voltages identified in step 606 have been applied (see step 610), then the system will determine the hard bits based on the sensing operations from the one or more iterations of step 608. In step 614, the system will determine the soft bits based on the sensing operations of the one or more iterations of step 608. In step 616, the hard bits and soft bits will be transferred from the memory chip to the Controller. In step 618, the Controller will determine the data being stored in the memory cells based on the hard bits and soft bits using a LDPC decoding process (or other ECC process). No specific ECC process is required for the technology described herein. Based on the decoding, the Controller will report the data to the host in step 620. Note that although FIG. 14 shows a set of steps in sequence, these steps may be performed in other orders. Additionally, two or more of the steps may be performed concurrently. For example, the steps of determining the hard bits, determining the soft bits and transferring hard bits and/or soft bits can be performed concurrently with each other and/or with step 608.

In one embodiment, the system will sense one hard bit and one soft bit for each read compare voltage. In one example implementation of this embodiment, there will be two sensing operations for each read compare voltage. A first sensing operation is performed on the memory cells connected to the common word line. This first sensing operation will sense whether the threshold voltage of the memory cells connected to the word line are greater than or less than the read compare voltage. A second sensing operation will be performed that concurrently tests a first subset of the memory cells connected to the word line for a first comparison voltage and a second subset of the memory cells connected to the word line for a second comparison voltage. Both the first subset of memory cells and second set of memory cells will be receiving the same word line voltage. In one example, the first subset of memory cells will be tested to determine whether their threshold voltages are greater than or less than a first soft bit compare voltage by applying a first voltage to the associated bit lines. The second set of memory cells are tested to determine whether their threshold voltages are less than or greater than a second soft bit compare voltage by applying a different voltage level to their bit lines.

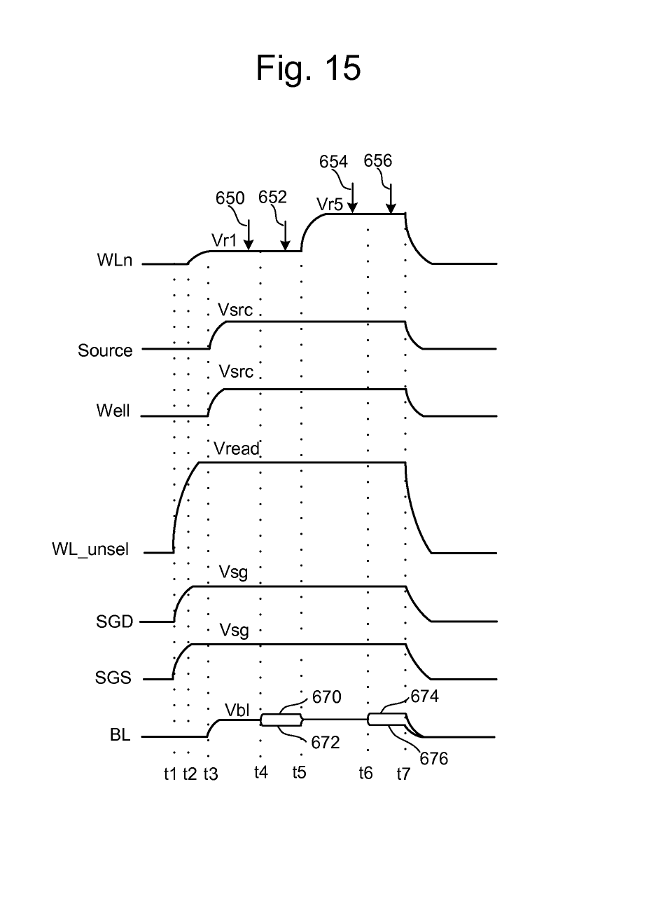

FIG. 15 is a timing diagram that depicts one example implantation of step 608 of FIG. 14, for the embodiment that includes two sensing operations, as discussed above. FIG. 15 shows seven signals: WLn, Source, Well, WL_unsel, SGD, SGS, and BL. WLn is the selected word line connected to the memory cells being read. The signal Source is the source line connected to all the NAND strings of a block (see FIG. 5). The signal Well is the voltage of the P-well region 182 (see FIG. 2). The signal WL_unsel is the voltage applied to the unselected word lines (those word lines for which connected memory cells will not be read). The signal SGD is the control signal for the drain side select gate. The signal SGS is the control signal for the source side select gate. The signal BL is the voltage of the various bit lines for the NAND strings having memory cells selected for reading. Initially all the seven signals are at ground (or near ground).

At time t1, SGD and SGS are raised to Vsg (e.g., approximately 3.5 volts). Also at t1, WL_unsel is raised to Vread, which can be between six and ten volts (e.g., approximately 7.4 volts). Vread is set high enough so that all the memory cells on the NAND string (other than the memory cells selected for reading, will be turned on and operated as pass gates. At time t2, the selected word line WLn is raised to a first read compare level. In the example of FIG. 15, it is assumed that the memory cells are being read to determine the lower page data; therefore, read operations are performed at Vr1 and Vr5 (see FIG. 12). At time t3, the Source line and Well line are raised to Vsrc (approximately 1.2 volts). Also at time t3, the bit line BL is raised to Vsrc. In some embodiments, the bit line can be raised to 0.3 volts higher than Vsrc. In other embodiments, the bit line could be raised to a value between 0.5-0.7 volts.

FIG. 15 shows a series of arrows 650, 652, 654 and 656 to indicate when sensing operations are performed. Arrow 650, between time t3 and t4 indicates a first sensing operation to determine whether the threshold voltage of the memory cells are above or below Vr1. Arrow 652, between time t4 and t5 indicates a second sensing operation which (in one embodiment) includes sensing soft bit information. During the second sensing operation, some of the memory cells connected to WLn will be sensed to determine whether their threshold voltages are less than or greater than Vr1+Δ and other memory cells will be tested to determine whether their threshold voltages are greater than or less than Vr1−Δ. To accomplish this concurrent sensing of soft bit information, some of the bit lines are raised to a higher bit line voltage Vb1+Δ (see portion 670 of BL) while other memory cells have their bit lines lowered to Vb1−Δ (see portion 672 of bit line voltage). Those memory cells connected to bit lines that are raised to Vb1+Δ will be sensed for Vr1+Δ (Vr12) and those memory cells connected to bit lines that are lowered to Vr1−Δ (672) will be tested to see whether their threshold voltages are less than or greater than Vr1−Δ (Vr11).

At time t5, the bit line goes back to Vb1 and the word line is raised from Vr1 to Vr5. Arrow 654, between time t5 and time t6, indicates a sensing operation to determine whether the threshold voltage of the memory cells are above or below Vr5. At this time, the bit line voltage is at Vb1. Arrow 656, between time t6 and time t7 indicates a sensing operation to concurrently determine whether some memory cells have their threshold voltages above or below Vr5+Δ (Vr52) and whether some memory cells have their threshold voltages above or below Vr5−Δ (Vr51). To test the memory cells for Vr5+Δ, the associated bit lines are raised to Vb1+Δ (674). To test memory cells against Vr5−Δ, the associated bit lines are lowered to Vb1−Δ (676). At time t7, all the signals are dissipated to ground.

Note in the embodiment discussed above, there are two sensing operations for each read compare voltage applied to the word line, with the first sensing operation being at the read compare voltage and the second sensing operation including two concurrent operations at offsets based on the results of the first sensing operation. Other embodiments can perform other permutations for the two sensing operations. For example, the soft bit information can be sensed first, or a subset of the soft bit information can be concurrently sensed with the hard bit information followed by another sensing operation for the remainder of the soft bit information. The embodiments of FIG. 15 illustrate that the memory cells are tested at multiple compare voltages consecutively and (for some) concurrently, all before changing the word line voltage to the next read compare voltage. That is, sensing operation 650 and 652 are performed while the word line WLn is at Vr1. After raising WLn to Vr5, then the sensing operation 654 and 656 are performed to Vr5.

As discussed above, in the second sensing operation, some of the memory cells are tested against the read compare voltage+Δ while other memory cells are tested against the read compare voltage−Δ. For a given memory cell, it is determined whether to test against the read compare voltage+Δ or the read compare voltage−Δ based on the sensing of the hard bit information. Therefore, the choice of which soft bit read compare to use for a given memory cell is determined dynamically and in real time based on the first sensing of hard bit information. For example, when the first sensing operation is at Vr1, those memory cells that turn on in response to Vr1 will be tested against Vr11, while those memory cells that do not turn on in response to Vr1 are tested against Vr12.

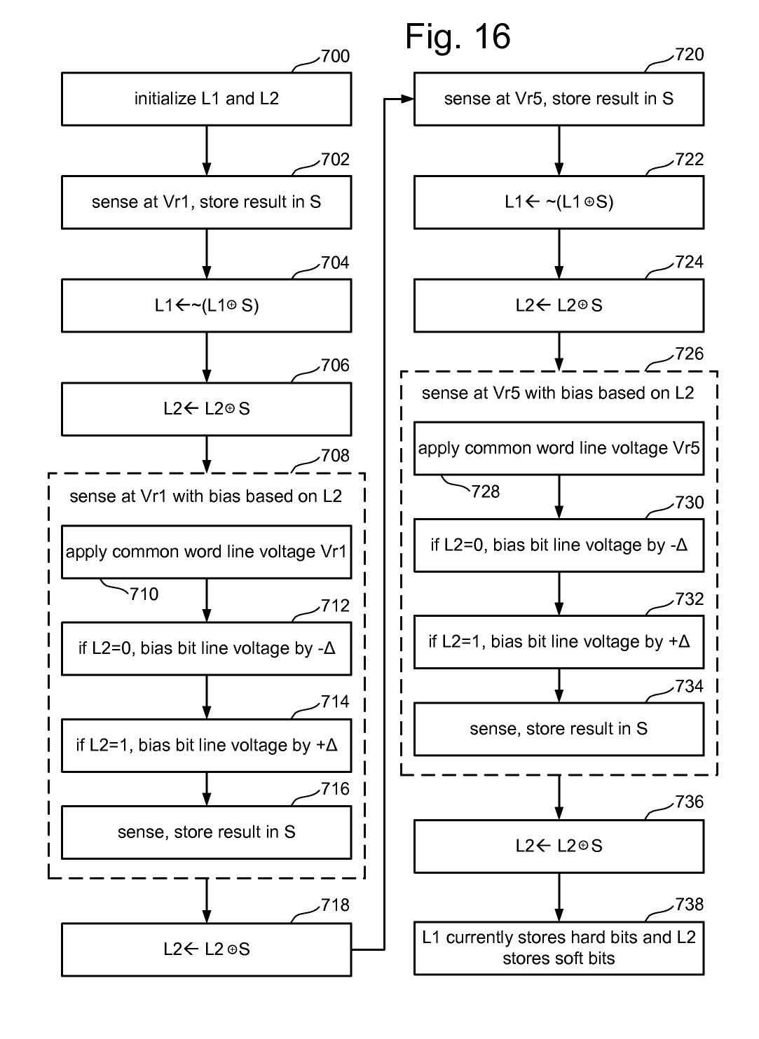

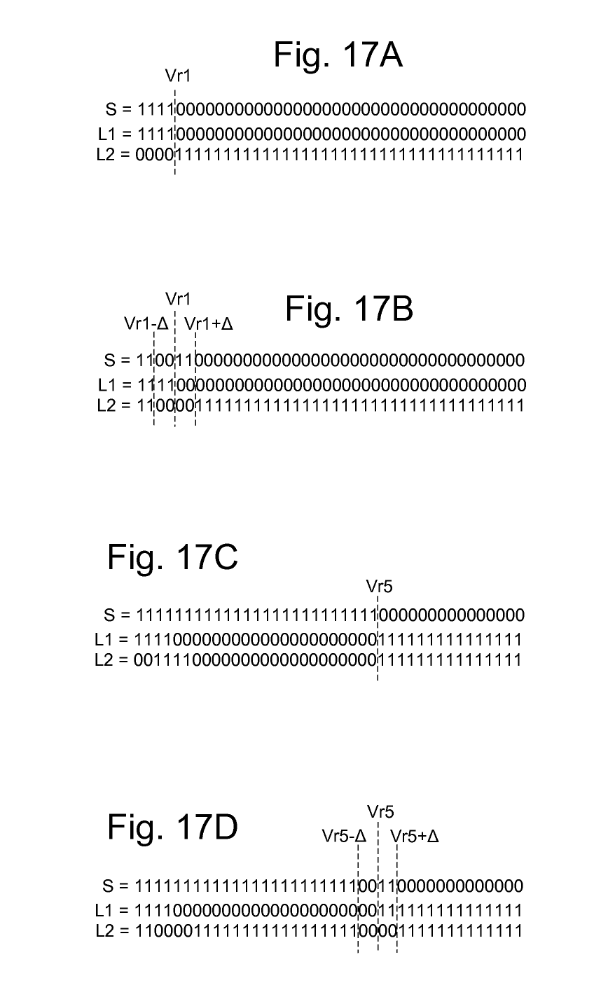

FIG. 16 is a detailed flow chart describing one example implementation of step 608-614 of FIG. 14, that utilizes the technology described above with respect to FIG. 15. The process of FIG. 16 utilizes latches L1 and L2 for each bit line (see FIG. 4A). FIGS. 17A-17D accompany FIG. 16 and will be used to graphically illustrate the contents of latches L1 and L2 during the process of FIG. 16. The process of FIG. 16 is performed by the memory chip.

In step 700 of FIG. 16, latches L1 and L2 (for each bit line) are initialized. In one embodiment, the latches are initialized to all 1's. Other embodiments may initialize the latches to other conditions. In step 702, the system will sense the memory cells connected to the selected word line WLn at the read compare voltage Vr1. The process of FIG. 16 assumes that the lower page data (see FIG. 12) is being read from memory cells that store three bits of data per memory cell and are connected to a common word line (the selected word line WLn). Therefore, the memory cells must be read at Vr1 and Vr5. Step 702 includes sensing at Vr1 and the results are stored in the sense amplifier latch, which will be referred to herein as S. Step 702 corresponds to arrow 650 of FIG. 15. In step 704, latch L1 (for each bit line) is loaded with the inverse of the exclusive-or of the pre-existing value of latch 1 and the results of the latest sensing operation being stored in the sense amplifier latch S (the results of the last sensing at Vr1). L1=NOT (L1 XOR S). FIG. 17A shows the contents of latch S and latch L1 after step 704. Note that the bits of the latch are arranged in order from lowest threshold voltage (left side) to highest threshold voltage (right side) for readability purposes. In a real flash memory device, the threshold voltages will be randomly distributed.

In step 706, latch L2 is loaded with the results of exclusive-or between the pre-existing values of latch L2 and the sense amplifier latch S (the results of the previous sensing at Vr1), L2=L2 XOR S. FIG. 17A depicts the contents of latch L2 after step 706. FIG. 17A also shows a vertical dashed line. Those bits to the left of the vertical dashed line are for memory cells that have threshold voltages less than Vr1. Those bits to the right of the dashed line are for memory cells that have a threshold voltage greater than Vr1. During the sensing, those memory cells that have a threshold voltage less than Vr1 will turn on and conduct current. For those memory cells that conduct current in response to the sense operation, the sense amplifier will store a 1 in the latch S. For those memory cells that do not turn on in response to the read compare voltage Vr1, the sense amplifiers will store 0. Therefore, at the end of step 706, latch L1 indicates a 1 if the memory cell turned on in response to Vr1.

Step 708 of FIG. 16 includes performing a second sensing operation, corresponding to arrow 652 of FIG. 15. In this second sensing operation, some memory cells will be sensed at Vr1+Δ while other memory cells will be concurrently sensed at Vr1−Δ. This concurrent sensing at two different levels is referred to as sensing at the read compare voltage with a conditional bias, where the conditional bias is based on the corresponding bit latch L2. Therefore, the conditional biasing is based on the reading at the read compare value, which is analogous to biasing based on the hard bit information. Those memory cells that turn on in response to Vr1 will be tested in the second sensing operation against Vr1−Δ. Those memory cells that do not turn on in response to Vr1, will be tested against Vr1+Δ. The two sensings will be performed concurrently. Step 708 includes performing sub-steps 710-716. In sub-step 710, the common word line voltage Vr1 will continue to be applied to the common word line, as depicted in FIG. 15. In sub-step 712, bit lines whose corresponding bit in latch L2 is equal to 0 will be biased by −Δ. In other words, a bit line with a corresponding bit in latch L2 that is equal to 0 will receive a voltage of Vr1−Δ. In sub-step 714, those bit lines whose corresponding bit in latch L2 is set to 1 will be biased by +A. In other words, those bit lines have a corresponding bit of L2 equal to 1, will receive Vr1+Δ. In sub-step 716, sensing operations will be performed (see arrow 652 of FIG. 15). The results of the sensing operations will be overwritten into the sense amplifier latch S.

FIG. 17B shows the results of step 716 stored in sense amplifier latch S. Due to the dynamic and conditional biasing, the results stored in latch S and depicted in 17B differ from the results stored in latch S depicted 17A because two bits have been flipped from 1 to 0. These two bits correspond to memory cells whose threshold voltage is greater than Vr1−Δ but less than Vr1. Additionally, two bits have flipped from 0 to 1. These two bits that flip from 0 to 1 are for memory cells whose threshold voltage is greater than Vr1 but less than Vr1+Δ. In step 718, latch L2 is loaded with the exclusive-or of its pre-existing contents and the current data stored in sense amplifier latch S, L2=L2 XOR S. The results of step 718 are depicted in FIG. 17B, showing the contents of latch L2. Note that latch L1 in 17B will depict the same results as in 17A since it has not been loaded after step 704.

In step 720, the system will sense the memory cells at Vr5. In other words, the system will test whether the memory cells have a threshold voltage less than or greater than read compare value Vr5. In one embodiment, as depicted in FIG. 15 at time t5, Vr5 is applied to the word line connected to the memory cells selected for reading. The results of the sensing operation (see arrow 654 of FIG. 15) it is stored in sense amplifier latch S, as depicted in FIG. 17C. Note that FIG. 17C shows a vertical dashed lined labeled Vr5. Those memory cells to the left of the vertical dashed line have threshold voltages less than Vr5; therefore, the data bits in latch S will be 1. Those memory cells having a threshold voltage greater than Vr5 will not turn on in response to Vr5 and the sense amplifier will thereby store data 0 in its latch. In step 722, latch L1 is loaded with the inverse of the exclusive-or operation between the pre-existing contents of latch L1 and the most recent sensing operation, L1=NOT (L1 XOR S). In step 724, L2 is loaded with the results of the exclusive-or operation between the pre-existing contents of L2 and the current contents of the sense latch S, L2=L2 XOR S. The results of step 722 and 724 are depicted in FIG. 17C.

In step 726, the system will sense at Vr5 with a bias that was dynamically determined in real time based on contents of L2 (which is based on the hard bit information). Step 726 includes four sub-steps 728-734. In sub-step 728, the common word line voltage is continued to be applied to the common word line. For example, FIG. 15 shows Vr5 continuing to be applied to word line WLn between times t6 and t7. In sub-step 730, those memory cells whose associated bits in L2 are set at 0, will have their bit lines bias by −Δ. Therefore, for a given NAND string, if the corresponding bit of L2=0, then the bit line voltage will be equal to Vr5−Δ (676 of FIG. 15). If L2=1 for that NAND string, then the bit line receives Vr5+Δ (see 674) in sub-step 732. In sub-step 734, sensing operation is performed, as depicted by arrow 656 in FIG. 15. The results of the sensing operation is stored in the sense amplifier latch S. FIG. 17D shows the results of step 734 of the data stored in S. In step 736, latch L2 is loaded with the results of an exclusive-or operation between the pre-existing data in latch L2 and the latest sensing results stored in S, L2=L2 XOR S. FIG. 17D shows the results in L2 after step 736. At this point, L1 stores the hard bits and L2 stores the soft bits (step 738).

The embodiments of FIGS. 15-17D assume the sensing of one hard bit and one soft bit for each read compare voltage. However, in other embodiments, more than one soft bit can be sensed. The process of FIG. 14 can be performed with two or more soft bits. The more soft bits read, the more accurate the decoding process will be. However, the more soft bits read, the more time it takes to perform the read process. Thus there is a trade off between number of soft bits, time to perform the read, and accuracy. In embodiments that read additional soft bits, the operation of FIG. 15 would be adapted to add additional sensing levels at each read compare voltage. For example, before WLn is raised from Vr1 to Vr5, an additional one or more sensing operations will be performed after sensing operation 652. Similar additional sensing operations will be performed after sensing operation 656. Additionally, the technology described with respect to FIGS. 15-17D will also apply to reading any of the other logical pages of a memory cell, or reading any other structure of data from nonvolatile storage.

The previous embodiments were based on the ability to perform conditional sensing (i.e. biasing of the second reading voltage would depend on the reading of the first reading voltage). There are other ways to perform these additional soft bit read information.

In flash memory systems, the threshold voltage of a memory cell is determined by applying a read compare voltage to the control gate. As discussed above, if the memory cell's threshold voltage is smaller than the applied read compare voltage, the memory cell will be conducting and the current on the bit line will be sensed by a sense amplifier. This is usually accomplished by charging a capacitor in the sense amplifier. The voltage on the capacitor is compared against a test level after a predetermined integration time. If the voltage on the capacitor is greater than the test level, then the threshold voltage of the memory cell being tested is considered to be lower than the applied read compare voltage. That is, if the threshold voltage of the memory cell is lower than the applied read compare voltage, the memory cell will turn on and the NAND string will conduct. Since the NAND string conducts, a node in the sense amplifier will charge up based on the capacitor connected to that node. On the other hand, if the voltage on the capacitor is lower than the test value, then the threshold voltage of the memory cell being tested is considered to be higher than the read compare voltage applied to the control gate of the memory cell. Of course, other implementations may be considered where the capacitor voltage is lowered in light of current through the NAND string such that a capacitor with a voltage higher than the test voltage means the threshold voltage is higher than the compare voltage being applied to the memory cell. Other circuit implementations can also be used for the sense amplifier. No particular sense amplifier circuit is required.

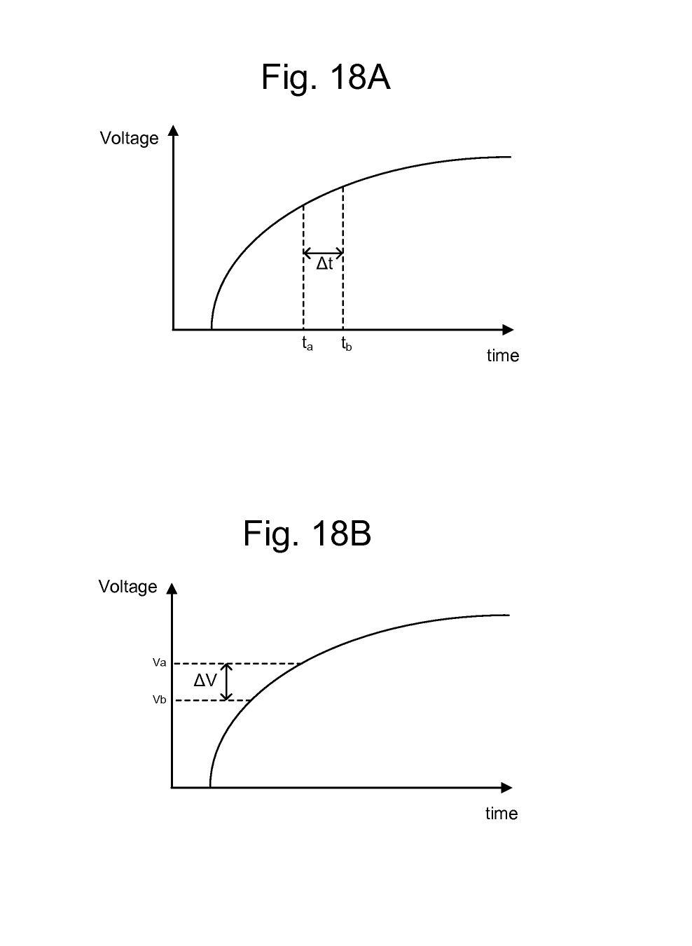

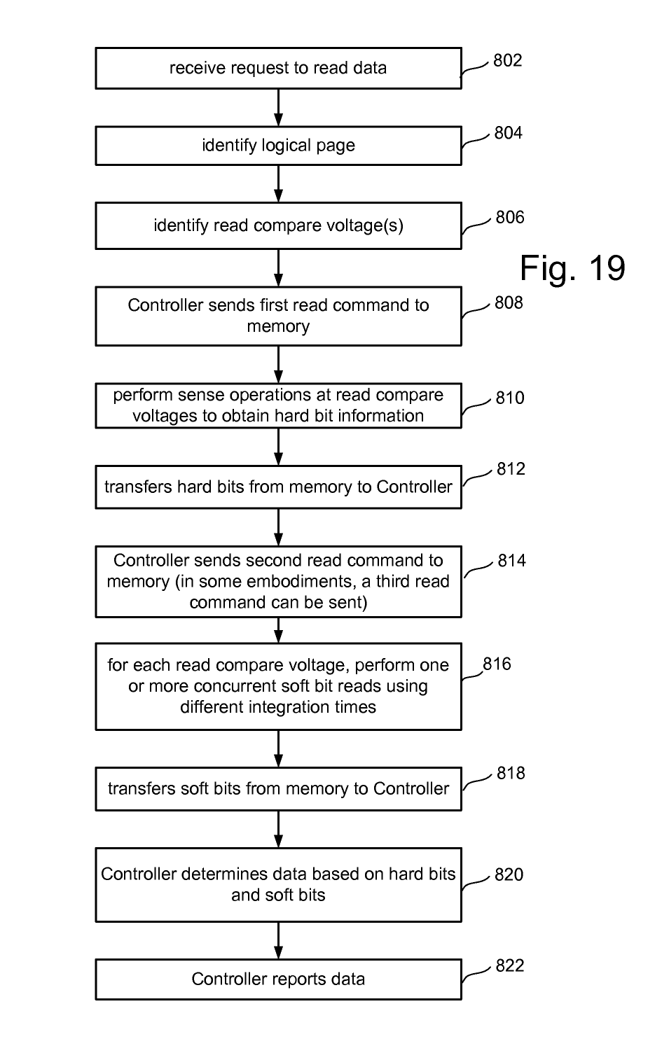

Different integration times or different sense amplifier test levels (test level for the voltage across the capacitor) can be used in order to emulate sensing at different threshold voltage levels while applying the same control gate voltage. This observation can be used for sensing multiple threshold voltages, in a single sensing operation, for the sake of fast soft bit reading. For example, applying a read compare voltage to a word line and sensing after a first integration time may correspond to sensing with a read compare voltage of V1 and sensing at a different time may correspond to sensing at a read compare voltage of V1−Δ. This concept is illustrated in FIG. 18A which plots voltage versus time for the voltage of a capacitor in a sense amplifier during a sense operation. If the memory cell turns on and responds to a control gate voltage applied to the word line, the current will flow through the NAND string and will cause the capacitor to charge up over time, as indicated in FIG. 18A. The sensed voltage at integration time tₐ is different than the sense threshold voltage at integration time t_{b}. If these two integration times are confined to a certain region, the difference in the sense threshold voltage may be proportional to the difference in time Δt. However, such linear behavior is limited since the curve tends to flatten with long integration times, and the readings become noisy for long integration times. Therefore, practical estimations must confine the integration time to a predefined region. This in turn gives a limited number of different of threshold voltages that the system can test in a single sensing operation. Looking at FIG. 18A, with the same voltage being applied to a common word line, memory cell tested after time tₐ will be effectively tested at a lower threshold voltage by ΔV than a memory cell connected to the same word line sensed later at time t_{b} (where tₐ differs from t_{b} by Δt).

Alternatively, if there is change in the integration time, the system can test for different threshold voltages by testing the capacitor voltage against different test voltages. FIG. 18B shows two test voltages Va and Vb which differ by ΔV.

FIGS. 19-29 describe a set of embodiments that include, while applying each of the word line voltages, sensing hard bit and soft bit information including concurrently sensing the plurality of memory cells at multiple comparison voltages associated with the applied word line voltage by testing for different currents through the nonvolatile storage elements.

FIG. 19 is a flow chart describing one embodiment for sensing one hard bit and one soft bit for each read compare voltage by concurrently sensing the plurality of memory cells at multiple comparison voltages associated with the applied word line voltage by testing for different currents to the nonvolatile storage elements. In the embodiment of FIG. 19, the testing for different currents is performed by testing the voltage of the capacitor in the sense amplifier at different integration times. In step 802 of FIG. 19, a request to read data is received. In step 804, one or more logical pages storing that data are identified. In step 806, the Controller will identify the read compare voltages necessary to be used in order to read the identified logical pages (as explained above). In step 808, the Controller will send a first read command to the memory chip. In one embodiment the first read command is to read the hard bit. In other embodiments, the first read command could include reading a hard bit and a portion of the soft bit information. In step 810, the memory chip will perform one or more sense operations at read compare voltages necessary to obtain the hard bit information. In step 812, the hard bits are transferred from the memory to the Controller. In step 814, the Controller will send a second read command to the memory. In step 816, for each read compare voltage, one or more concurrent soft bit read operations are performed using different integration times. By using different integration times, the system can be concurrently sense for different currents. In step 818, the soft bit information is transferred from the memory to the Controller. Note that in some embodiments, the Controller can also issue a third command for additional soft bit information. In step 820, the Controller can determine the data stored in the nonvolatile storage based on the hard bits and soft bits it received from the memory. In step 822, the Controller will report the data that it determined in step 820.

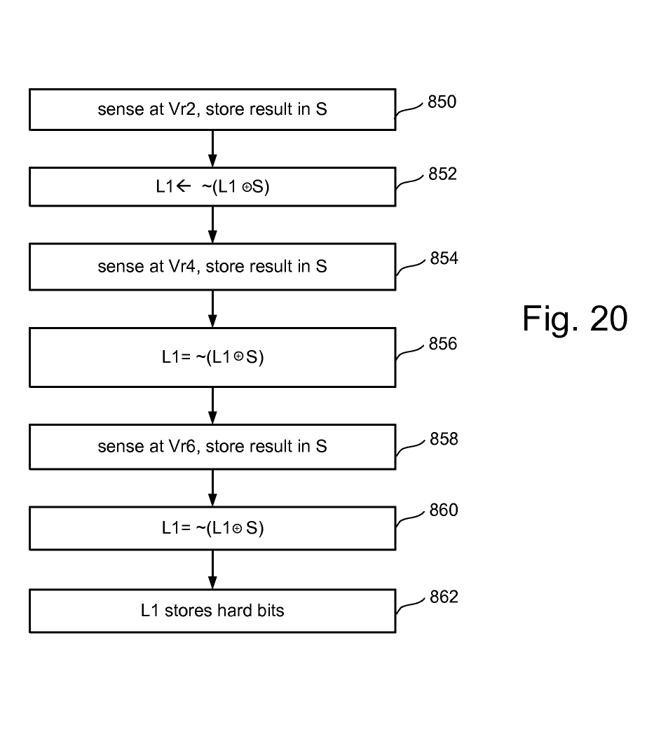

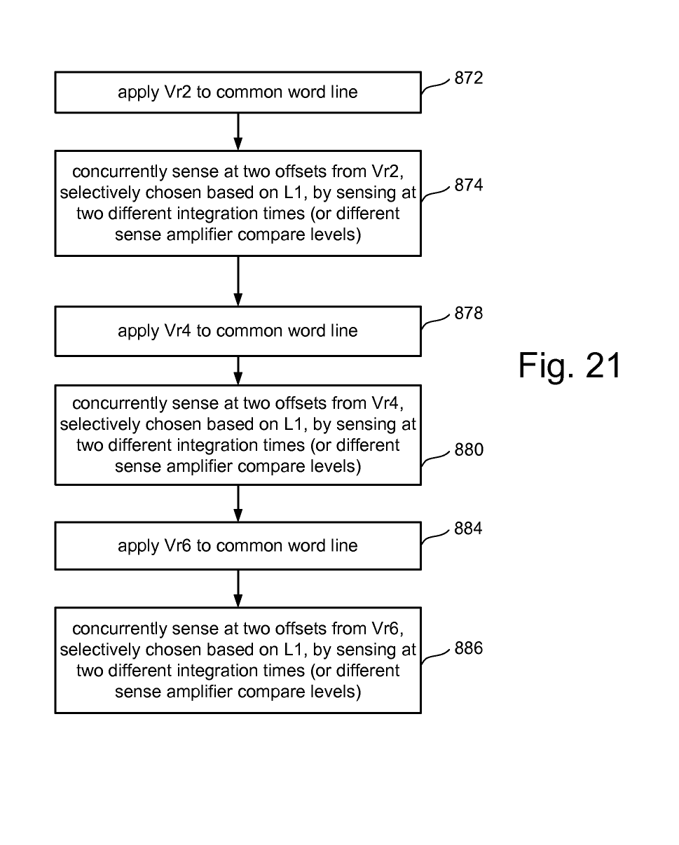

FIG. 20 is a flow chart describing one embodiment of a process for performing sense operations at read compare voltages to obtain hard bit information. FIG. 20, therefore, provides more details of one example implementation of step 810 of FIG. 19. For the example associated with FIG. 20 (and FIG. 21 discussed below), it is assumed that the read request received requires a reading of the middle page of data (see FIG. 12). Therefore, in step 806 of FIG. 19, the read compare voltages that are identified in order to read the middle page include Vr2, Vr4 and Vr6.

In step 850 of FIG. 20, the system will perform a sense operation at Vr2. For example, the voltage Vr2 will be applied to the selected word line WLn and a sense operation will be performed to see whether the memory cells connected to WLn have a threshold voltage less than or greater than Vr2. The results of that sensing operation will be stored in a sense amplifier latch S. Those memory cells that turned on in response to Vr2 because their threshold voltage is less than Vr2 will have a 1 stored in S. Those memory cells that did not turn on in response to Vr2 because they have a threshold voltage greater than Vr2 will have a 0 stored in S. In step 852, latch L1 (which was previously initialized as all 1's) is updated with the inverse of an exclusive- or operation between the previous data in L1 and the results of the latest sensing stored in sense amplifier latch S, L1=NOT (L1 XOR S).

In step 852, the system will sense whether the threshold voltages of the memory cells connected to the selected word line WLn are less than or greater than read compare voltage Vr4. The results are stored in sense amplifier latch S. That is, in one embodiment, read compare voltage Vr4 is applied to the selected word line WLn and those memory cells connected to WLn whose threshold voltage is less than Vr4 will conduct in response to Vr4. In step 856, latch L1 is updated to store the inverse of an exclusive-or operation between the previous contents of latch L1 and the results of the most recent sensing stored in sense amplifier latch S, L1=NOT (L1 XOR S).

In step 858, the system will sense the memory cells connected to the selected word line at Vr6 to determine whether the memory cells have a threshold voltage less than or greater than Vr6. The results are stored in sense amplifier latch S such that S will store 1 if the threshold voltage of the sensed memory cell is less than Vr6 and a 0 if the threshold voltage of the memory cell is greater than Vr6. In one example, this can be accomplished by applying Vr6 to the selected word line WLn, as discussed above. In step 860, latch L1 is updated to store the inverse of an exclusive-or operation between the previous contents of L1 and the latest sensing results stored in sense amplifier latch S, L1=NOT (L1 XOR S). At this point, L1 stores the hard bits (862).

FIG. 21 is one example implementation of step 816, including performing one or more concurrent soft bit reads using different integration times. Note that the processes of FIGS. 20 and 21 are performed by the memory chip.

In step 872 of FIG. 21, Vr2 is applied to the common word line. In step 874, the system will concurrently sense at two offsets from Vr2. These two offsets are selectively chosen based on the corresponding bit for L1. The concurrently sensing of two different offsets is accomplished by sensing at two different integration times. In other embodiments two different sense amplifier test levels can be used (as discussed above). The hard bit (sensed by Vr2) is stored in the L1 latch (same as in FIG. 20). The soft bit is stored in a second Latch L2 if selective sensing is enabled. If selective sensing is not enabled then we need two latches for storing the sense results L2 and L3. L2 will store the results of sensing with a low integration time, and L3 will store the result of sensing with the larger integration time. In step 878, read compare voltage Vr4 is applied to the common word line. In step 880, the system will concurrently sense at two offsets from Vr4, selectively chosen based on L1, by sensing at two different integration times (or different sense amplifier compare levels). In step 884, Vr6 is applied to the common word line. In step 886, the system will concurrently sense at two offsets from Vr6, selectively chosen based on L1, by sensing at two different integration times (or different sense amplifier compare levels). Note that steps 874, 880, and 886, concurrently sensing at two different offsets, include sensing at the two different soft bit compare levels by using two different integration times. After sensing at all points (Vr2, Vr4, Vr6) L2 and L3 may be NOT XOR-ed to produce the soft bit The soft bit will subsequently be transferred to the Controller (see step 818 of FIG. 19).

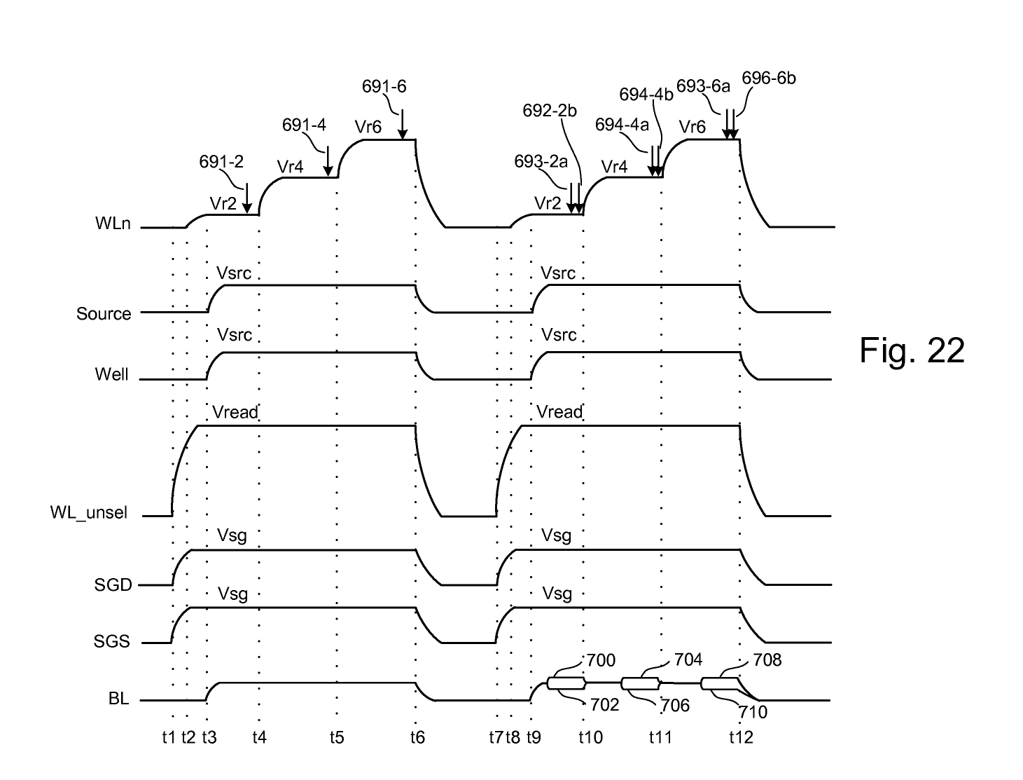

FIG. 22 is a timing diagram that graphically depicts the behavior during the processes of FIGS. 20 and 21. FIG. 22 illustrates the behavior of WLn, Source, Well, WL_unsel, SGD, SGS, and BL. Initially, all the signals are at ground (or close to ground). Times t1-t6 show an example implementation of the process of FIG. 20. At time t1, the unselected word lines WL_unsel are raised to Vread, SGD is raised at Vsg and SGS is raised to Vsg. At time t2, WLn is raised to Vr2. At time t3, the Source and Well lines are raised to Vsrc and the bit lines BL are raised to Vb1. In this embodiment, all of the bit lines will receive the same voltage. Arrow 691-2, between times t3 and t4 indicate a first sensing operation that corresponds to the sensing operation at Vr2 of step 850 in FIG. 20. At time t4, WLn is raised to Vr4. Arrow 691-4, between times t4 and t5, indicates a second operation corresponding to sensing at Vr4 of step 854. At time t5, WLn is raised to Vr6. Arrow 691-6, between t5 and t6, indicates a third sensing operation at Vr6 that corresponds to step 858. At time t6, all of the signals are dissipated down to ground.

Times t7-t12 of FIG. 22 correspond to the process of FIG. 21. At time t7, the unselected word lines WL_unsel are raised to Vread, SGD is raised to Vsg and SGS is raised to Vsg. At time t8, the selected word line WLn is raised to Vr2. At time t9, the Source line and Well line are raised to Vsrc and the bit line is raised to Vb1. Between t9 and t10, the system performs concurrent sensing at two offsets from Vr2 as per step 874 of FIG. 21. In one embodiment, the concurrent sensing at two offsets from Vr2 is performed by using two different integration times. Arrow 693-2a represents the conclusion of a first integration time and arrow 693-2b represents the conclusion of a second integration time (e.g., both at a constant bit line voltage).

In another embodiment, the concurrent sensing at two offsets from Vr2 is performed by using different sense amplifier compare levels. To accomplish this concurrent sensing of soft bit information, some of the bit lines are raised to a higher bit line voltage Vb1+Δ (see portion 700 of BL) while other memory cells have their bit lines lowered to Vb1−Δ (see portion 702 of bit line voltage). Those memory cells connected to bit lines that are raised to Vb1+Δ will be sensed for Vr2+Δ and those memory cells connected to bit lines that are lowered to Vb1−Δ (702) will be tested to see whether their threshold voltages are less than or greater than Vr1−Δ.

At t10, selected word line WLn is raised to Vr4. Between t10 and t11, the system performs concurrent sensing at two offsets from Vr4 as per step 880 of FIG. 21. In one embodiment, the concurrent sensing at two offsets from Vr4 is performed by using two different integration times. Arrow 693-4a represents the conclusion of a first integration time and arrow 693-4b represents the conclusion of a second integration time (e.g., both at a constant bit line voltage).

In another embodiment, the concurrent sensing at two offsets from Vr4 is performed by using different sense amplifier compare levels. To accomplish this concurrent sensing of soft bit information, some of the bit lines are raised to a higher bit line voltage Vb1+Δ (see portion 704 of BL) while other memory cells have their bit lines lowered to Vb1−Δ (see portion 706 of bit line voltage). Those memory cells connected to bit lines that are raised to Vb1+Δ (704) will be sensed for Vr4+Δ and those memory cells connected to bit lines that are lowered to Vb1−Δ (706) will be tested to see whether their threshold voltages are less than or greater than Vr4−Δ.

At time t11, the selected word line WLn is raised to Vr6. Between t11 and t12, the system performs concurrent sensing at two offsets from Vr6 as per step 886 of FIG. 21. In one embodiment, the concurrent sensing at two offsets from Vr6 is performed by using two different integration times. Arrow 693-6a represents the conclusion of a first integration time and arrow 693-6b represents the conclusion of a second integration time (e.g., both at a constant bit line voltage).

In another embodiment, the concurrent sensing at two offsets from Vr6 is performed by using different sense amplifier compare levels. To accomplish this concurrent sensing of soft bit information, some of the bit lines are raised to a higher bit line voltage Vb1+Δ (see portion 708 of BL) while other memory cells have their bit lines lowered to Vb1−Δ (see portion 710 of bit line voltage). Those memory cells connected to bit lines that are raised to Vb1+Δ (708) will be sensed for Vr6+Δ and those memory cells connected to bit lines that are lowered to Vb1−Δ (710) will be tested to see whether their threshold voltages are less than or greater than Vr6−Δ.

In one embodiment of a process that implements the function depicted in FIG. 22, each of the concurrent sensing (arrow 693-2, 693-4 and 693-6) includes performing both sensing operations on every memory cell. In another embodiment, each memory cell will be put into one of two groups where one of the groups senses at one offset from the read compare voltage and another group senses at the other offset from the read compare voltage, based on the value of the hard bit (as discussed above).

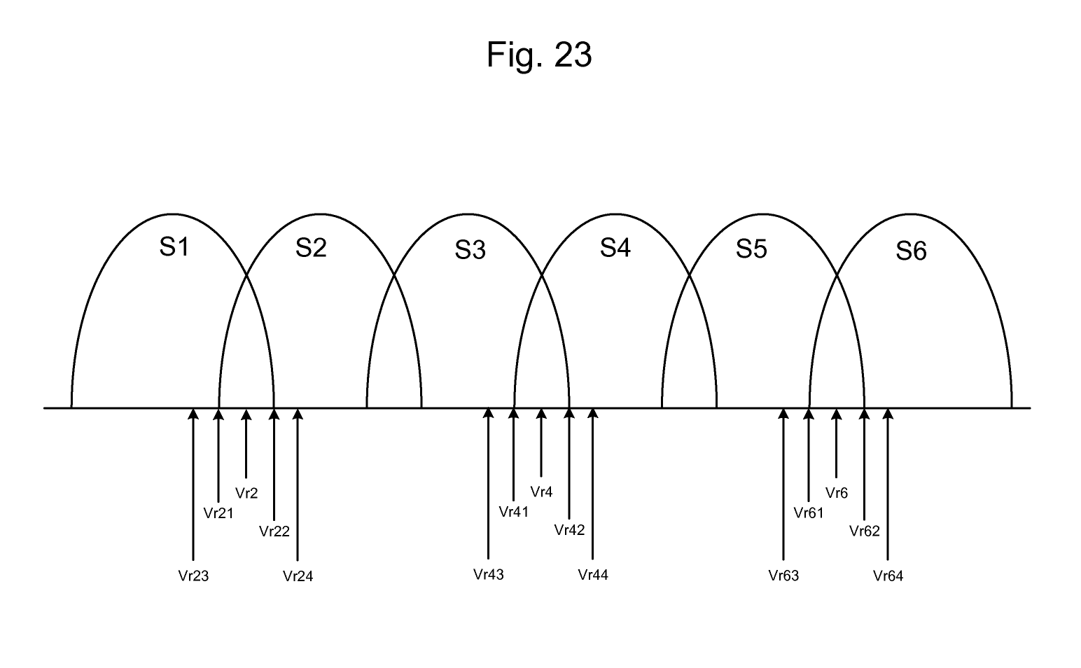

FIG. 23 displays threshold voltages for a system that uses two soft bits. Note that FIG. 23 displays states S1-S6 (with state S0 and S7 not being depicted; however, the system would include S0 as the erased state and state S7 as the highest programmed state). The examples discussed below will be with respect to reading the middle page of data, which includes sensing at Vr2, Vr4 and Vr6. FIG. 23 shows two soft bits associated with each of Vr2, Vr4 and Vr6. For example, a first soft bit associated with Vr2 identifies memory cells with threshold voltages between Vr21 and Vr22, a second soft bit associated with Vr2 identifies memory cells with threshold voltages between Vr23 and Vr24. A first soft bit associated with Vr4 identifies memory cells with threshold voltages between Vr41 and Vr42 and a second soft bit identifies memory cells with threshold voltages between Vr43 and Vr44. A first soft bit associated with Vr6 identifies memory cells with threshold voltages between Vr61 and Vr62 and a second soft bit identifies memory cells with threshold voltages between Vr63 and Vr64. In one embodiment, Vr21 and Vr22 differ from Vr2 by Δ, Vr23 and Vr24 differ from Vr2 by 2, Δ, Vr41 and Vr42 differ from Vr4 by Δ, Vr43 and Vr44 differ from Vr4 by 2Δ, Vr61 and Vr62 differ from Vr6 by Δ, and Vr63 and Vr64 differ by 2Δ.

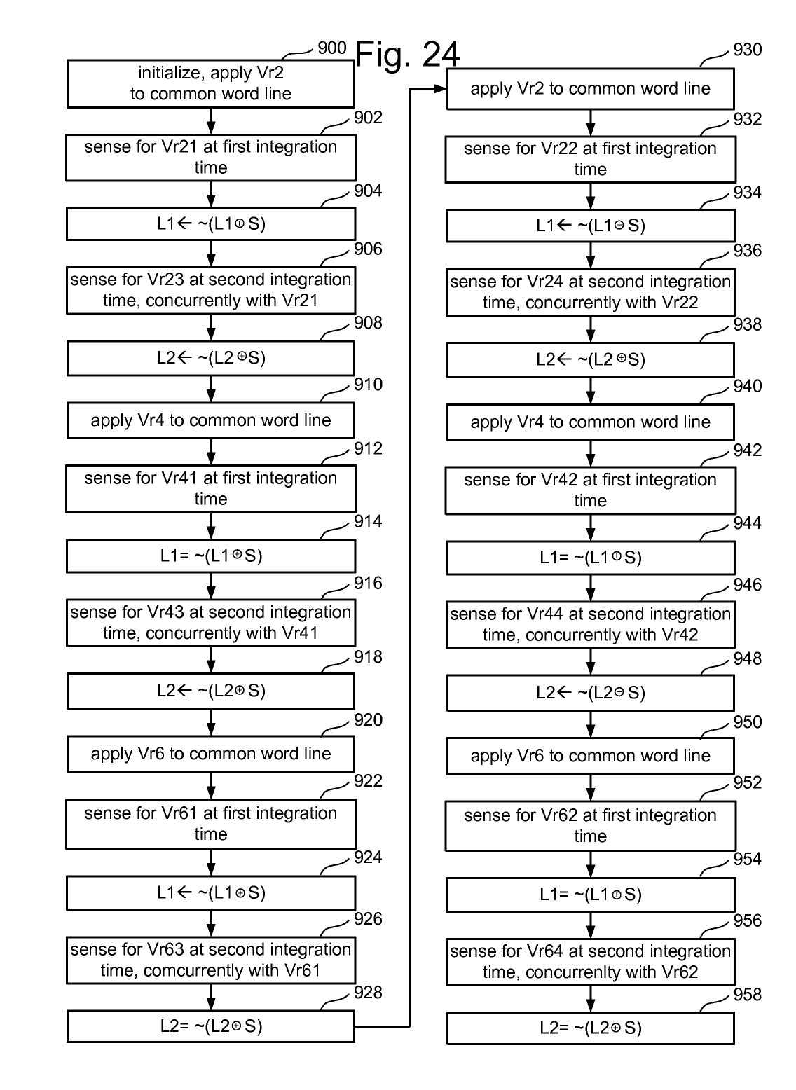

There are many different embodiments for reading data using two (or more) soft bits. One embodiment uses the process of FIG. 19, where steps 814 and 816 are performed twice. That is, the Controller will send a second read command (the first iteration of step 814) followed by sending a third read command (the second iteration of steps 814 and 816). Step 810 of FIG. 19 is still performed in the manner depicted with respect to FIG. 20. FIG. 24 is a flow chart describing one embodiment of a process for performing the two iterations of step 816 in order to read two soft bits of data.

In step 900 of FIG. 24, the latches are initialized and the read compare voltage Vr2 is applied to the common word line. In step 902, the system will sense for threshold voltages greater than or less than Vr21 by sensing at a first integration time. In step 904, latch L1 will be loaded with the inverse of an exclusive-or operation between the pre-existing contents of L1 and the results of the sensing of step 902 stored in sense amplifier latch S, L1=NOT (L1 XOR S). In step 906, the system will sense for threshold voltages less than or greater than Vr23 at a second integration time (different than the first integration time). Note that the sensing in step 902 is performed concurrently with the sensing of step 906 (both while Vr2 is applied to WLn). Although the second integration time happens later, the charging of the capacitor is happening concurrently. In some embodiments, every memory cell will be sensed twice (once at each integration time), while in other embodiments, each memory cell will only be sensed at one of the integration times depending on the hard bit data (or other data). In step 908, latch L2 is loaded with the inverse of an exclusive-or operation between the pre-existing contents of latch L2 and the results of the latest sensing stored in sense amplifier latch S, L2=NOT (L2 XOR S). Note that prior to the process of FIG. 24, latch L2 can be loaded with the results of the hard bit sensing.

In step 910, read compare voltage Vr4 is applied to the common word line. In step 912, the system will sense for threshold voltages greater than or less than Vr41 by sensing at a first integration time. In step 914, latch L1 is loaded with the inverse of an exclusive-or operation between the pre-existing contents of L1 and the results of the latest sensing stored in the sense amplifier latch S, L1=NOT (L1 XOR S). In step 916, the system will sense for threshold voltages less than or greater than Vr43 by sensing at a second integration time. The sensing of step 916 is performed concurrently with the sensing of step 912 (both while Vr4 is applied to WLn). In step 918, latch L2 is loaded with the inverse of an exclusive-or operation between the pre-existing contents of latch L2 and the results of the latest sensing stored in sense amplifier latch S, L2=NOT (L2 XOR S).

In step 920, read compare voltage Vr6 is applied to the common word line. In step 922, the system will sense for threshold voltages less than or greater than Vr61 by sensing at a first integration time. In step 924, latch L1 is loaded with the inverse of an exclusive-or operation between the pre-existing contents of latch L1 and the results of the latest sensing stored in the sense amplifier latch S, L1=NOT (L1 XOR S). In step 926, the system will sense for threshold voltages less than or greater than Vr63 by sensing at a second integration time. The sensing of step 926 is performed concurrently with the sensing of step 922. In step 928, latch L2 is loaded with the inverse of an exclusive-or operation between the pre-existing contents of latch L2 and the results of the latest sensing stored in sense amplifier latch S, L2=NOT (L2 XOR S). Note that both sensing operations 922 and 926 are performed while Vr6 is still applied to the common word line. Between steps 928 and 930, the Controller will issue the third read command (discussed above). At this stage L1 and L2 hold data from which the first soft bit can be computed and should send this data out to the controller and initialize L1 and L2.

In step 930, Vr2 is applied to the common word line. In step 932, the system will sense for threshold voltages greater than or less than Vr22 by sensing at a first integration time. In step 934, latch L1 is loaded with the inverse of an exclusive-or operation between the pre-existing contents of L1 and the results of the latest sensing stored in the sense amplifier latch S, L1=NOT (L1 XOR S). In step 936, the system will sense for threshold voltages less than or greater than Vr24 by sensing at a second integration time. Step 936 is performed concurrently with step 932. Note that the sensing of step 936 and the sensing of step 932 are both performed while Vr2 is applied to the common word line.

In step 940, Vr4 is applied to the common word line. In step 942, the system will sense for threshold voltages less than or greater than Vr42 by sensing at a first integration time. The latch L1 is loaded with an inverse of an exclusive-or operation between the pre-existing contents of L1 and the results of the latest sensing stored in the sense amplifier latch S, L1=NOT (L1 OR S). In step 946, the system will sense for threshold voltages being less than or greater than Vr44 by sensing at a second integration time. Sensing operation of step 946 is performed concurrently with the sensing operation of step 942, and both are performed while Vr4 is applied to the common word line. In step 948, the latch L2 is loaded with the inverse of an exclusive-or operation between the pre-existing contents of latch L2 and the results of the latest sensing stored in the sense amplifier latch S.

In step 950, Vr6 is applied to the common word line. In step 952, the system will sense for whether threshold voltages of the memory cells are less than or greater than Vr62 by sensing at a first integration time. In step 954, latch L1 is loaded with the inverse of an exclusive-or operation between the pre-existing contents of latch L1 and the results of the latest sensing operation stored in the sense amplifier S, L1=NOT (L1 XOR S). In step 956, the system will sense for whether threshold voltages are less than or greater than Vr64 by sensing at a second integration time. The sensing of step 956 is performed concurrently with the sensing of step 952, and both sensing steps are performed while VR6 is applied to the common word line. In step 958, L2 is loaded with the inverse of an exclusive-or operation between the pre-existing contents of L2 and the results of the latest sensing operations stored in the sense amplifier latch S, L2=NOT (L2 XOR S).

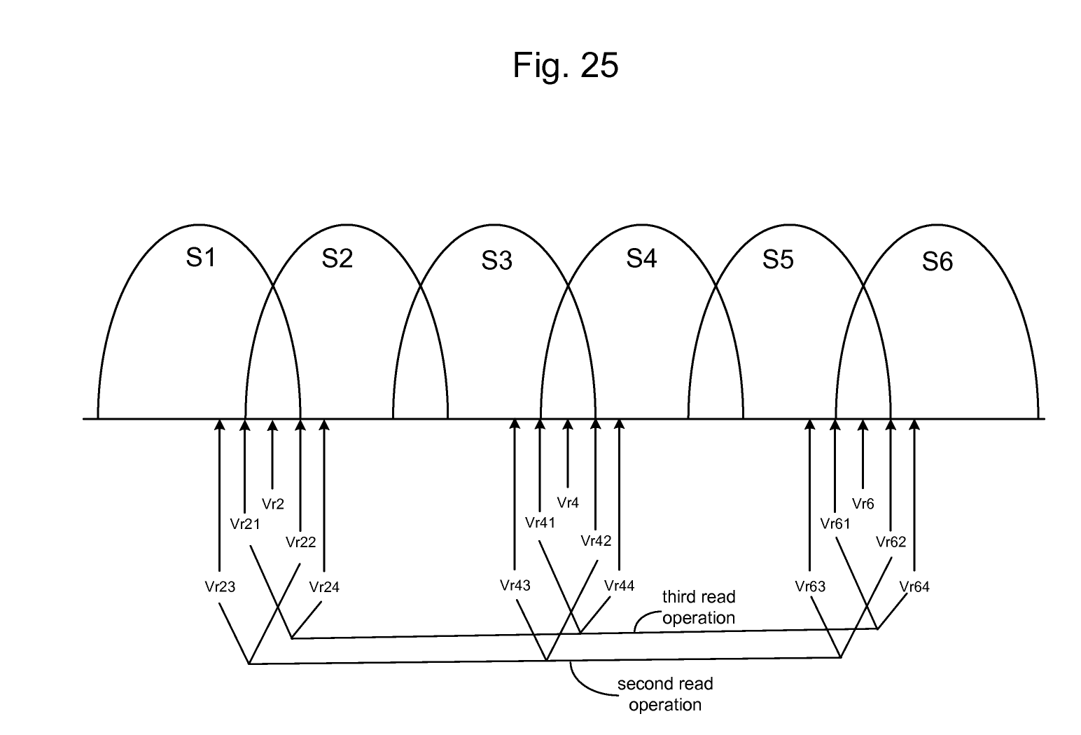

FIG. 25 shows the same threshold distributions S1-S6 discussed above (S0 and S7 are omitted from the figure for ease of reading, but would be included in the system) in order to show another embodiment of a process for reading that includes two soft bits. In this embodiment, like the previous embodiment, the Controller will issue three read commands to the memory chip. The first read command will be for hard bit information. The second read command and the third read command will be for soft bit information. FIG. 25 graphically depicts which soft bit information is read as part of the second read operation (response to the second read command) and which soft bit information is read as part of the third read operation (in response to the third read operation). For example, in the second read operation, the system will concurrently read information at Vr23 and Vr22, concurrently read information at Vr43 and Vr42, and concurrently read information at Vr63 and Vr62. During the third read operation, the system will concurrently read information at Vr21 and Vr24, concurrently read information at Vr41 and Vr44, and concurrently read information at Vr61 and Vr64. [

It may be more intuitive to determine the first soft bit from reading Vr21 and Vr22, and the second soft bit by reading Vr23 and Vr24. However as noted above (in relation to FIGS. 18A and 18B) there is a maximal span for the difference between two voltages which are read concurrently. If Vr23 and Vr24 are read concurrently then this maximal span, denoted ΔV, limits the voltage difference between Vr23 and Vr24. However, with the current implementation the voltage difference between Vr23 and Vr24 may be extended to 4/3ΔV, since Vr23 and Vr24 are not read together. Instead Vr23 and Vr22 are read together so the difference between them is at most ΔV. The difference between Vr23 and Vr24 is 4/3 larger. The soft bits which are achieved by the current implementation are equivalent to the more intuitive soft bits obtained by reading the first soft bit from reading Vr21 and Vr22, and the second soft bit by reading Vr23 and Vr24].

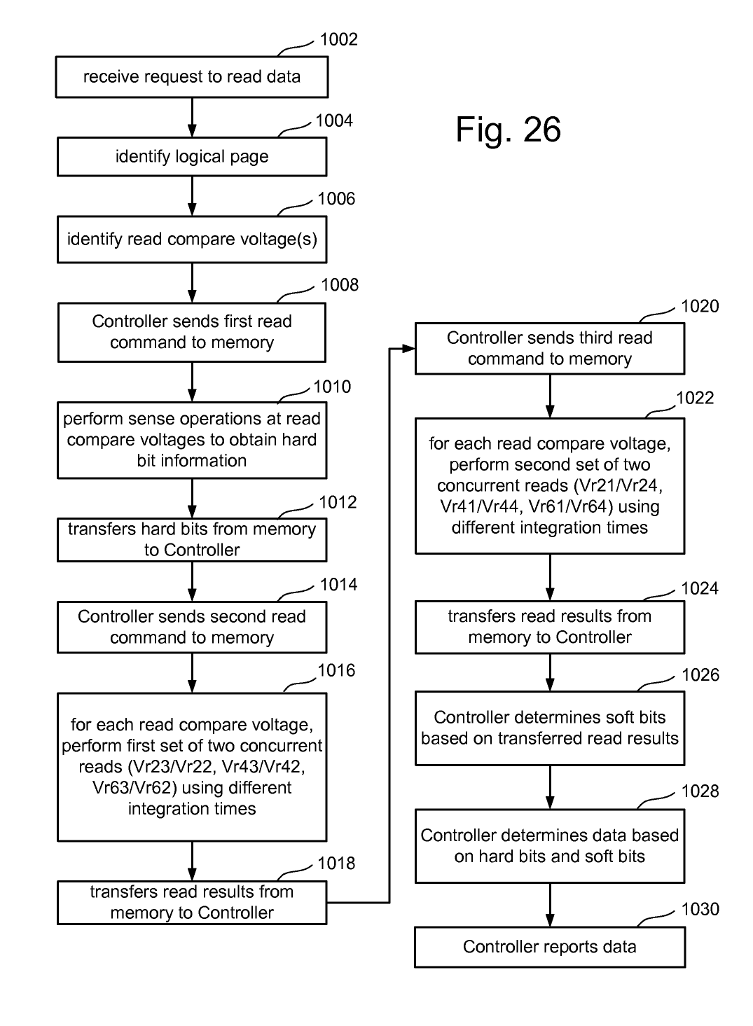

FIG. 26 is a flow chart describing one example process for reading data according to the embodiment of FIG. 25. In step 1002, the system will receive a request to read data. For example, a Controller can receive a read request from a host. Alternatively, the read request can be generated from the Controller or other entity. In step 1004, the appropriate one or more logical pages that is storing the data are identified, as discussed above. In step 1006, the Controller (or other entity) will identify the appropriate one or more read compare voltages in order to access the data from the appropriate identified logical pages, as discussed above. In step 1008, the Controller will send a first read command to the memory chip. In step 1010, the memory chip will perform a series of sense operations at the read compare voltages identified in step 1006 in order to obtain hard bit information. In one embodiment, step 1010 is implemented by performing the process of FIG. 20. In step 1012, the hard bits are transferred from the memory chip to the Controller. In step 1014, the Controller will send a second read command to the memory. In response to the second read command, in step 1016, the memory chip will perform a second set of read operations. For each read compare voltage identified in step 1006, a first set of two concurrent soft bit reads will be performed using two integration times. For example, the system will perform reads at Vr23/Vr22, Vr43/Vr42 and Vr63/Vr62. In one embodiment, step 1016 is implemented by performing the process of FIG. 21. In step 1018, the information sensed in step 1016 is transferred from the memory chip to the Controller. In step 1020, the Controller will send a third read command to the memory chip. In step 1022, the memory chip performs a set of read operations. For each read compare voltage identified in step 1006, a second set of two concurrent reads will be performed including concurrently reading information for Vr21/Vr24, concurrently reading information for Vr41/Vr44, and concurrently reading information for Vr61/Vr64 using different integration times.

In one embodiment, step 1022 is implemented by performing the process of FIG. 21. In step 1024, the memory will transfer the results from step 1014 to the Controller. In step 1026, the Controller determines the soft bits based on the transferred read results. In step 1018, the Controller will determine the data stored by the memory cells based on the hard bits and soft bits. In step 1020, the Controller will report the data.

Several variants may be considered for determining the soft bits by reading concurrently at Vr23/Vr22, Vr43/Vr42 and Vr63/Vr62 (step 1016) and reading concurrently at Vr21/Vr24, Vr41/Vr44 and Vr61/Vr64 (step 1014 (right)).

A first variant will comprise the steps of:

1. Storing Vr23, Vr43, Vr63 into a latch L3, and Storing Vr22, Vr42, Vr62 into a latch L2

2. Storing Vr21, Vr41, Vr61 into a latch L1, and Storing Vr24, Vr44, Vr64 into a latch L4.

3. Determining the two soft bits by performing the NOT XOR of L1 and L2 for the first soft bit and NOT XOR of L3 and L4 for the second soft bit.

4. Transferring the two soft bits to the controller

A second variant will differ from the first by sending the contents of the latches to the controller, and computing the soft bits in the controller.

A third variant may use selective sensing. According to this variant, when applying Vr23 and Vr22 concurrently, only one of the results (per memory cell) may be stored in a latch, according to the reading of the hard bit. For example if the hard bit related to voltage Vr2 was to the left of Vr2 (e.g. the memory is SLC and the hard bit was read as 1), then only the Vr23 result is saved in a latch L1. The readings of Vr43 and Vr42, and the readings of Vr63 and Vr64 are used for updating the contents of L1, (as was done in previous examples)

Similarly, the readings of Vr21 and Vr24 and Vr41/Vr44 Vr61/Vr64 will be read in a similar way, and the result will be stored in latch L2 for all the other reading voltages. The result will be that L1 and L2 will hold soft bit information, Ŝ1, Ŝ2. The mapping of the soft bit information into voltage regions is illustrated in FIG. 30. The ordinary soft bits are denoted as S1 and S2, and the soft bits of the current variant are denoted Ŝ,Ŝ2. One way of using the soft bits Ŝ1,Ŝ2 is by converting them to ordinary soft bit via:

S1=Ŝ2⊕HB∪ Ŝ̅1̅⊕ H̅B̅

S2=Ŝ1⊕HB∪ Ŝ̅2̅⊕ H̅B̅

This may be done by performing the computation of the ordinary soft bits from the ‘selective’ soft bits. Alternatively, a look up table may be defined to directly determine an LLR value for each value of the ‘selective’ soft bits, (or rather each combination of values of the hard bit and Ŝ1, Ŝ2).

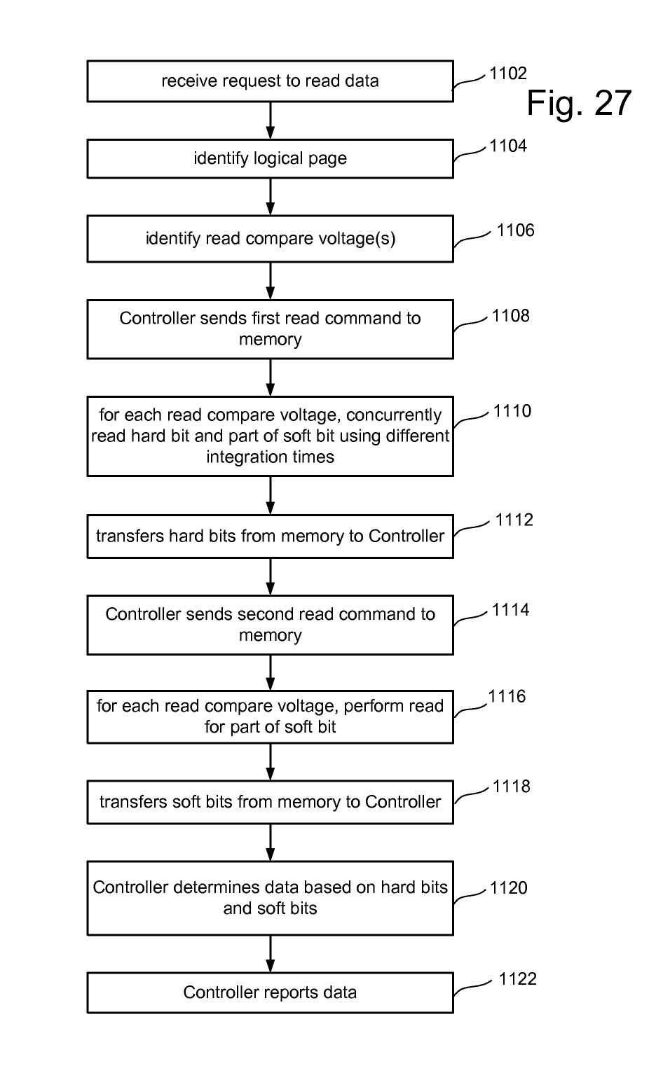

FIG. 27 is a flow chart describing an embodiment of a process for reading data that includes reading one soft bit. However, two read commands are used to read one hard bit and one soft bit. In a previous embodiment discussed above, a first read command was for reading the hard bit and a second read command was for reading the soft bit. In the embodiment of FIG. 27, the first read command is for reading the hard bit information and part of the soft bit information, while the second read command is for reading the remainder of the soft bit information. This is an example of splitting up the reading of the soft bit information into different read operations.

In step 1102 of FIG. 27, a request to read data is received. In step 1104, the logical page(s) storing that data is identified by the Controller. In step 1106, the Controller will identify one or more read compare voltages necessary to read the identified logical page(s). In step 1108, the Controller will send a first read command to the memory chip. In step 1110, for each read compare voltage identified in step 1106, the memory chip will concurrently read hard bit information and part of the soft bit information using two different integration times. In step 1112, the hard bits read in step 1110 are transferred from the memory to the Controller. In step 1114, the Controller will send a second read command to the memory. In step 1116, for each read compare voltage identified in step 1106, the memory chip will perform read operations to obtain the remaining portion of the soft bit information. In step 1118, the remaining soft bit information is transferred from the memory to the Controller. In step 1120, the Controller determines the data read based on the hard bits and soft bits. In step 1122, the Controller will report the data read. Note that the process of FIG. 27 (as well as the other flow charts included herein) can be performed in a different order.

In one embodiment, the soft bit information from step 1110 and from step 1116 are combined by a NOT XOR operation. There are several variants for implementation. The first is to send the readings of 1116 to the controller, and the controller performs the NOT XOR. The second is to perform the NOT XOR in the memory (e.g. in dedicated latches), and send the result (the soft bit) to the controller. A third variant would be to directly use the readings of 1116 as input to a look up table that generates the LLRs (skip the computation of the soft bit). This variant is most preferable in terms of performance at the price of a small increase of memory size

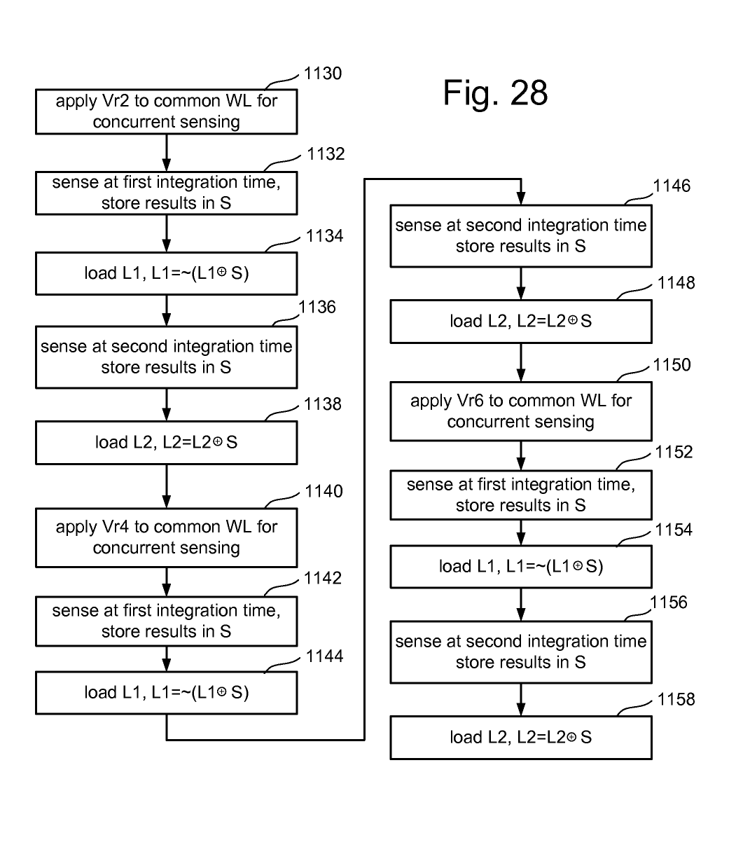

FIG. 28 is a flow chart describing one embodiment of a process for concurrently reading hard bit information and part of the soft bit information using different integration times. The process of FIG. 28 is one example implementation of step 1110 of FIG. 27. In step 1130 of FIG. 28, the read compare voltage Vr2 is applied to the common word line for concurrent sensing, as discussed below. In step 1132, sensing is performed at the first integration time. This sensing is to obtain hard bit information. The results of the sensing is stored in the sense amplifier latch S. In step 1134, latch L1 (which has been previously initialized to all 1's) is loaded with the inverse of the exclusive-or operation between the pre-existing data in L1 and the results of the latest sensing stored in sense amplifier latch S, L1=NOT (L1 XOR S). In step 1136, the memory chip will sense at the second integration time and store that result in sense amplifier latch S. In step 1138, latch L2 (which has been previously initialize to all 1's) is loaded with the results of exclusive-or operation between the pre-existing data in latch L2 and the results of the latest sensing stored in sense amplifier S, L2=L2 XOR S. Note that the sensing of steps 1132 and 1136 are performed concurrently and while Vr2 is applied to the common word line.

In step 1140, read compare voltage Vr4 is applied to the common word line for concurrent sensing. In step 1142, the memory chip will sense at a first integration time, and store the results in sense amplifier latch S. In step 1144, latch L1 is loaded with the inverse of an exclusive-or operation between the pre-existing contents of L1 and the results of the latest sensing stored in sense amplifier latch S, L1=NOT (L1 XOR S). In step 1146, the memory chip will sense at the second integration time and store the results in sense amplifier latch S. In step 1148, latch L2 will be loaded with the results of an exclusive-or operation between the pre-existing contents of latch L2 and the results of the latest sensing stored in sense amplifier S, L2=L2 XOR S).

In step 1150, Vr6 is applied to the common word line for concurrent sensing. In step 1152, the memory chip will sense at the first integration time and store the results in sense amplifier latch S. In step 1154, latch L1 is loaded with the inverse of an exclusive-or operation between the pre-existing contents of L1 and the results of the latest sense operation stored in sense amplifier latch S, L1=NOT (L1 XOR S). In step 1156, the memory chip will sense at a second integration time and store the results in sense amplifier latch S. In step 1158, latch L2 will be loaded with the results from the exclusive-or operation between the pre-existing contents of latch L2 and the results of the latest sensing stored in sense amplifier latch S, L2=L2 XOR S, Note that the sensing in steps 1152 and 1156 are performed concurrently and with Vr6 being applied to the common word line.

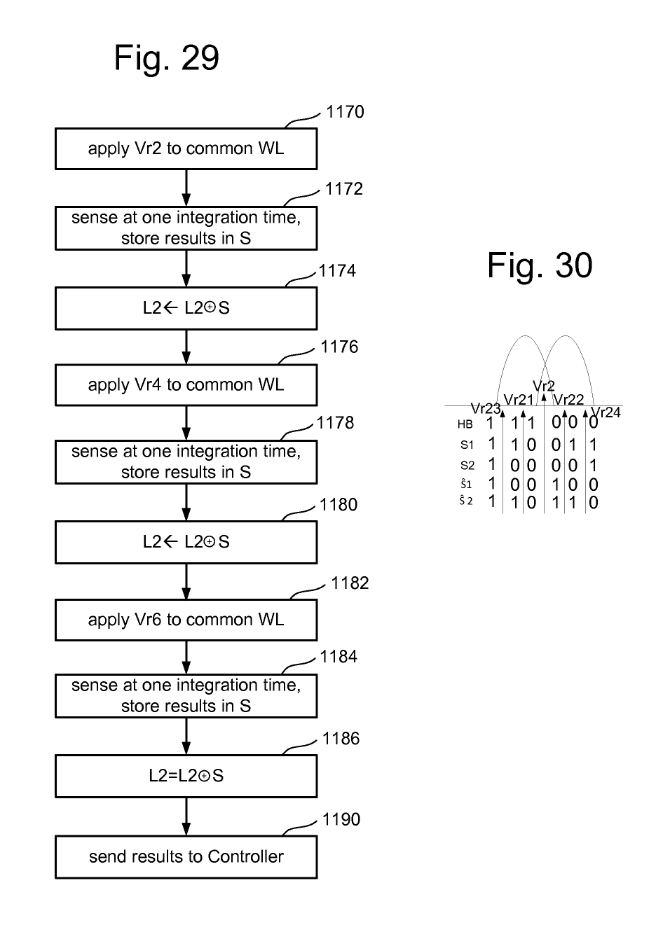

FIG. 29 is a flow chart describing one embodiment of a process for performing read operations for part of a soft bit. The process of FIG. 29 is one example implementation of step 116 of FIG. 27. In step 1170, the read compare voltage Vr2 is applied to the common word line. In step 1172, the memory chip will sense the memory cells at one integration time and store the results in sense amplifier latch S. In step 1174, latch L2 is updated to store the results of an exclusive-or operation between L2 and the results of the latest sense operation stored in sense amplifier latch S, L2=L2 XOR S. In step 1176, read compare voltage Vr4 is applied to the common word line. In step 1178, the memory chip will sense the memory cells at one integration time and store the results in sense amplifier latch S. In step 1180, latch L2 will be updated to store the results of an exclusive-or operation between the pre-existing contents of latch L2 and the results of the previous sensing operation stored in sense amplifier S, L2=L2 XOR S. In step 1182, Vr6 is applied to the common word line. In step 1184, the memory chip will sense the memory cells at one integration time and store the results in sense amplifier latch S. In step 1186, latch L2 will be updated to store the results of an exclusive-or operation between the pre-existing contents of latch L2 and the results of the latest sense operation stored in sense amplifier latch S, L2=L2 XOR S. In step 1190, the results of step 1186 (the soft bits) are transmitted to the controller.

One embodiment includes applying a set of word line voltages to a word line connected to a plurality of non-volatile storage elements. Each word line voltage is associated with a plurality of comparison voltages that are lower than comparison voltages for higher word line voltages and higher than comparison voltages for lower word line voltages. While applying each of the word line voltages to the word line, the method senses the plurality of non-volatile storage elements at comparison voltages associated with the applied word line voltage before applying a next word line voltage of the set. The method further includes computing hard bits and soft bits as a function of the sensing.

One embodiment includes a plurality of non-volatile storage elements and one or more control circuits in communication with the plurality of non-volatile storage elements. The one or more control circuits apply a set of word line voltages to a word line connected to the plurality of non-volatile storage elements. Each word line voltage is associated with a plurality of comparison voltages that are lower than comparison voltages for higher word line voltages and higher than comparison voltages for lower word line voltages. While applying each of the word line voltages to the word line the one or more control circuits sense the plurality of non-volatile storage elements at comparison voltages associated with the applied word line voltage before applying a next word line voltage of the set. The one or more control circuits compute hard bits and soft bits as a function of the sensing.

One embodiment includes applying a set of word line voltages to a word line connected to a plurality of non-volatile storage elements. Each word line voltage is associated with a plurality of comparison voltages that are lower than comparison voltages for higher word line voltages and higher than comparison voltages for lower word line voltages. The method further includes, while applying each of the word line voltages, sensing hard bit and soft bit information including concurrently sensing the plurality of non-volatile storage elements at multiple comparison voltages associated with the applied word line voltage by testing for different currents through the non-volatile storage elements. The method further includes computing hard bits and soft bits as a function of the hard bit and soft bit information.

One embodiment includes a plurality of non-volatile storage elements and one or more control circuits in communication with the plurality of non-volatile storage elements. The one or more control circuits apply a set of word line voltages to a word line connected to a plurality of non-volatile storage elements. Each word line voltage is associated with a plurality of comparison voltages that are lower than comparison voltages for higher word line voltages and higher than comparison voltages for lower word line voltages. While applying each of the word line voltages the one or more control circuits sense hard bit and soft bit information including concurrently sensing the plurality of non-volatile storage elements at multiple comparison voltages associated with the applied word line voltage by testing for different currents through the non-volatile storage elements. The one or more control circuits compute hard bits and soft bits as a function of the hard bit and soft bit information.

The foregoing detailed description has been presented for purposes of illustration and description. It is not intended to be exhaustive or limiting to the precise form disclosed. Many modifications and variations are possible in light of the above teaching. The described embodiments were chosen in order to best explain the principles of the disclosed technology and its practical application, to thereby enable others skilled in the art to best utilize the technology in various embodiments and with various modifications as are suited to the particular use contemplated. It is intended that the scope be defined by the claims appended hereto.

We claim:

1. A method for reading hard bits and soft bits from non-volatile storage, comprising:
applying a set of word line voltages to a word line connected to a plurality of non-volatile storage elements, each word line voltage is associated with a plurality of comparison voltages that are lower than comparison voltages for higher word line voltages and higher than comparison voltages for lower word line voltages;
while applying each of the word line voltages to the word line, sensing the plurality of non-volatile storage elements at comparison voltages associated with the applied word line voltage before applying a next word line voltage of the set; and
computing hard bits and soft bits as a function of the sensing.

2. The method of claim 1, wherein sensing the plurality of non-volatile storage elements at comparison voltages associated with the applied word line voltage comprises:
sensing at least two comparison voltages concurrently.

3. The method of claim 2, wherein sensing at least two comparison voltages concurrently comprises:
sensing a first subset of the non-volatile storage elements connected to the word line for a first comparison voltage while a first voltage is applied to bit lines for the first subset of the non-volatile storage elements and a particular word line voltage is applied to the word line; and
sensing a second subset of the non-volatile storage elements connected to the word line for a second comparison voltage while a second voltage is applied to bit lines for the second subset of the non-volatile storage elements and the particular word line voltage is applied to the word line.

4. The method of claim 2, wherein sensing at least two comparison voltages concurrently comprises:
sensing a first subset of the non-volatile storage elements connected to the word line for a first comparison voltage at a first sensing time in response to the applied word line voltage; and
sensing a second subset of the non-volatile storage elements connected to the word line for a second comparison voltage at a second sensing time in response to the applied word line voltage.

5. The method of claim 2, wherein sensing at least two comparison voltages concurrently comprises:
charging capacitors associated with the non-volatile storage elements in response to current flowing in at least some of the non-volatile storage elements;
sensing a first subset of the non-volatile storage elements connected to the word line for a first comparison voltage by testing whether an associated capacitor has reached a first voltage level; and
sensing a second subset of the non-volatile storage elements connected to the word line for a second comparison voltage by testing whether an associated capacitor has reached a second voltage level.

6. The method of claim 1, wherein sensing the plurality of non-volatile storage elements at comparison voltages associated with the applied word line voltage comprises:
performing a first sensing of the non-volatile storage elements connected to the word line for the applied compare voltage; and
performing a second sensing of the non-volatile storage elements that concurrently tests a first subset of the non-volatile storage elements connected to the word line for a first comparison voltage and a second subset of the non-volatile storage elements connected to the word line for a second comparison voltage, the hard bits are computed as a function of the first sensing and the soft bits are computed as a function of the second sensing.

7. The method of claim 6, wherein sensing the plurality of non-volatile storage elements at comparison voltages associated with the applied word line voltage further comprises:
determining whether each of the non-volatile storage elements should be tested for the first comparison or the second comparison for the second sensing based on results of the first sensing.

8. The method of claim 6, wherein:
the first sensing and second sensing is performed consecutively for each word line voltage before performing sense operations for other word line voltages during a common read process to read a common set of data; and
testing the first subset of the non-volatile storage elements connected to the word line for the first comparison voltage includes applying a first bit line voltage to the first subset of the non-volatile storage elements; and
testing the second subset of the non-volatile storage elements connected to the word line for the second comparison voltage includes applying a second bit line voltage to the second subset of the non-volatile storage elements while applying the first bit line voltage to the first subset of the non-volatile storage elements.

9. The method of claim 6, wherein the computing hard bits and soft bits as a function of the sensing comprises:
storing in a first latch results of NOT XOR between the first latch and results of the first sensing;
storing in a second latch results of XOR between the second latch and results of the first sensing; and
storing in the second latch results of XOR between the second latch and results of the second sensing, at the end of the method the first latch stores hard bits and the second latch stores soft bits.

10. The method of claim 1, wherein:
the consecutively applying the set of word line voltages comprises applying a set of read compare voltages in ascending order without discharging to ground between read compare voltages;
the sensing of the non-volatile storage elements is performed according to ascending order of the word line voltages.

11. A non-volatile storage apparatus that can read hard bits and soft bits, comprising:
a plurality of non-volatile storage elements; and
one or more control circuits in communication with the plurality of non-volatile storage elements, the one or more control circuits apply a set of word line voltages to a word line connected to the plurality of non-volatile storage elements, each word line voltage is associated with a plurality of comparison voltages that are lower than comparison voltages for higher word line voltages and higher than comparison voltages for lower word line voltages, while applying each of the word line voltages to the word line the one or more control circuits sense the plurality of non-volatile storage elements at comparison voltages associated with the applied word line voltage before applying a next word line voltage of the set, and the one or more control circuits compute hard bits and soft bits as a function of the sensing.

12. The non-volatile storage apparatus of claim 11, wherein:
the one or more control circuits sense the plurality of non-volatile storage elements at comparison voltages associated with the applied word line voltage by performing a first sensing of the non-volatile storage elements connected to the word line for the applied compare voltage and performing a second sensing of the non-volatile storage elements that concurrently test a first subset of the non-volatile storage elements connected to the word line for a first comparison voltage and a second subset of the non-volatile storage elements connected to the word line for a second comparison voltage.

13. The non-volatile storage apparatus of claim 12, wherein:
the one or more control circuits concurrently test the first subset of the non-volatile storage elements connected to the word line for the first comparison voltage and the second subset of the non-volatile storage elements connected to the word line for the second comparison voltage by sensing a first subset of the non-volatile storage elements connected to the word line for a first comparison voltage while a first voltage is applied to bit lines for the first subset of the non-volatile storage elements and a particular word line voltage is applied to the word line and sensing a second subset of the non-volatile storage elements connected to the word line for a second comparison voltage while a second voltage is applied to bit lines for the second subset of the non-volatile storage elements and the particular word line voltage is applied to the word line.

14. The non-volatile storage apparatus of claim 12, wherein:
the one or more control circuits concurrently test the first subset of the non-volatile storage elements connected to the word line for the first comparison voltage and the second subset of the non-volatile storage elements connected to the word line for the second comparison voltage by sensing a first subset of the non-volatile storage elements connected to the word line for a first comparison voltage at a first sensing time and sensing a second subset of the non-volatile storage elements connected to the word line for a second comparison voltage at a second sensing time.

15. The non-volatile storage apparatus of claim 12, wherein:
the one or more control circuits concurrently test the first subset of the non-volatile storage elements connected to the word line for the first comparison voltage and the second subset of the non-volatile storage elements connected to the word line for the second comparison voltage by charging capacitors associated with the non-volatile storage elements in response to current flowing in at least some of the non-volatile storage elements, sensing a first subset of the non-volatile storage elements connected to the word line for a first comparison voltage by testing whether an associated capacitor has reached a first voltage level and sensing a second subset of the non-volatile storage elements connected to the word line for a second comparison voltage by testing whether an associated capacitor has reached a second voltage level.

16. The non-volatile storage apparatus of claim 11, wherein:
the one or more control circuits include a controller and on-memory circuits;
the on-memory circuits compute hard bits and soft bits as a function of the sensing by storing in a first latch a result of NOT XOR between the first latch and results of the first sensing, storing in a second latch a result of XOR between the second latch and results of the first sensing, and storing in the second latch a result of XOR between the second latch and results of the second sensing;
the on-memory circuits transmit contents of the first latch as hard bits and contents of the second latch as soft bits to the controller;
the controller determines data stored in the non-volatile storage elements based on the hard bits and the soft bits;
the on-memory circuits perform the sensing; and
the on-memory circuits perform the applying the set of word line voltages to a word line

17. A method for reading hard bits and soft bits from non-volatile storage, comprising:
applying a set of word line voltages to a word line connected to a plurality of non-volatile storage elements, each word line voltage is associated with a plurality of comparison voltages that are lower than comparison voltages for higher word line voltages and higher than comparison voltages for lower word line voltages;
while applying each of the word line voltages, sensing hard bit and soft bit information including concurrently sensing the plurality of non-volatile storage elements at multiple comparison voltages associated with the applied word line voltage by testing for different currents through the non-volatile storage elements; and
computing hard bits and soft bits as a function of the hard bit and soft bit information.

18. The method of claim 17, wherein concurrently sensing the plurality of non-volatile storage elements at multiple comparison voltages associated with the applied word line voltage by testing for different currents through the non-volatile storage elements comprises:
sensing a first subset of the non-volatile storage elements connected to the word line for a first comparison voltage at a first sensing time in response to the applied word line voltage; and
sensing a second subset of the non-volatile storage elements connected to the word line for a second comparison voltage at a second sensing time in response to the applied word line voltage.

19. The method of claim 17, wherein concurrently sensing the plurality of non-volatile storage elements at multiple comparison voltages associated with the applied word line voltage by testing for different currents through the non-volatile storage elements comprises:
charging capacitors associated with the non-volatile storage elements in response to current flowing in at least some of the non-volatile storage elements;
sensing a first subset of the non-volatile storage elements connected to the word line for a first comparison voltage by testing whether an associated capacitor has reached a first voltage level; and
sensing a second subset of the non-volatile storage elements connected to the word line for a second comparison voltage by testing whether an associated capacitor has reached a second voltage level.

20. The method of claim 17, wherein sensing hard bit and soft bit information comprises:
performing a first sensing of the non-volatile storage elements connected to the word line for a read compare voltage; and
performing a second sensing of the non-volatile storage elements that concurrently tests a first subset of the non-volatile storage elements connected to the word line for a first comparison voltage using a first sensing time and a second subset of the non-volatile storage elements connected to the word line for a second comparison voltage using a second sensing time, the hard bits are computed as a function of the first sensing and the soft bits are computed as a function of the second sensing.

21. The method of claim 17, wherein the sensing hard bit and soft bit information and computing hard bits and soft bits as a function of the hard bit and soft bit information comprises:
applying a multiple read compare voltages to the word line;
sensing the non-volatile storage elements at the multiple read compare voltages;
loading into a first latch results of NOT XOR between the first latch and results of the sensing the non-volatile storage elements at the multiple compare voltages, after which the first latch stores the hard bits;
transferring the hard bits from the first latch to a controller.
applying the multiple read compare voltages to the word line;
concurrently sensing the non-volatile storage elements at multiple offsets from the read compare voltages;
loading into the first latch results of NOT XOR between the first latch and results of the concurrently sensing the non-volatile storage elements at multiple offsets from the read compare voltages, after which the first latch stores the soft bits;
transferring the soft bits from the first latch to the controller; and
using the soft bits and hard bits at the controller to determine data stored in the non-volatile storage elements.

22. The method of claim 21, wherein:
the concurrently sensing the non-volatile storage elements at multiple offsets from the read compare voltages includes sensing for a first offset at a first sense time and sensing for a second offset at a second sense time.

23. The method of claim 17, wherein the sensing hard bit and soft bit information and computing hard bits and soft bits as a function of the hard bit and soft bit information comprises:
applying multiple read compare voltages to the word line;
for each read compare voltage, concurrently sensing hard bit information and soft bit information by sensing the hard bit information from the non-volatile storage elements at a first sense time and the soft bit information from the non-volatile storage elements at a second sense time;
loading into a first latch results of NOT XOR between the first latch and results of the sensing the hard bit information, after which the first latch stores the hard bits;
loading into a second latch results of XOR between the second latch and results of the sensing the soft bit information;
transferring the hard bits from the first latch to a controller.
applying the multiple read compare voltages to the word line;
sensing the non-volatile storage elements at offsets from the read compare voltages;
loading into the second latch results of XOR between the second latch and results of the sensing the non-volatile storage elements at offsets from the read compare voltages, after which the first second stores the soft bits;
transferring the soft bits from the first latch to the controller; and
using the soft bits and hard bits at the controller to determine data stored in the non-volatile storage elements.

24. The method of claim 17, wherein sensing soft bit information and computing soft bits comprises:
applying multiple read compare voltages to the word line;
for each read compare voltage applied to the word line, concurrently sensing the non-volatile storage elements at multiple offsets from the read compare voltages by sensing for a first offset at a first sense time and for a second offset at a second sense time;
loading into a first latch results of NOT XOR between the first latch and sensing for the first offset;
loading into a second latch results of NOT XOR between the first latch and sensing for the second offset;
applying the multiple read compare voltages to the word line;
for each read compare voltage applied to the word line, concurrently sensing the non-volatile storage elements at multiple offsets from the read compare voltages by sensing for a third offset and for a fourth offset at different sense times;
loading into the first latch results of NOT XOR between the first latch and sensing for the third offset;
loading into the second latch results of NOT XOR between the first latch and sensing for the fourth offset;
transferring contents of the first latch as first soft bits to a controller;
transferring contents of the second latch as second soft bits to the controller; and
using the soft bits at the controller to determine data stored in the non-volatile storage elements.

25. The method of claim 24, wherein:
the first offset and the second offset are lower than the respective read compare voltage; and
the third offset and the fourth offset are higher than the respective read compare voltage.

26. The method of claim 24, wherein:
the first offset and the third offset are lower than the respective read compare voltage; and
the second offset and the fourth offset are higher than the respective read compare voltage.

27. A non-volatile storage apparatus that can read hard bits and soft bits, comprising:
a plurality of non-volatile storage elements; and
one or more control circuits in communication with the plurality of non-volatile storage elements, the one or more control circuits apply a set of word line voltages to a word line connected to a plurality of non-volatile storage elements, each word line voltage is associated with a plurality of comparison voltages that are lower than comparison voltages for higher word line voltages and higher than comparison voltages for lower word line voltages, while applying each of the word line voltages the one or more control circuits sense hard bit and soft bit information including concurrently sensing the plurality of non-volatile storage elements at multiple comparison voltages associated with the applied word line voltage by testing for different currents through the non-volatile storage elements, the one or more control circuits compute hard bits and soft bits as a function of the hard bit and soft bit information.

28. The non-volatile storage apparatus of claim 27, wherein:
the one or more control circuits test for different currents through the non-volatile storage elements by sensing a first subset of the non-volatile storage elements connected to the word line for a first comparison voltage at a first sensing time and sensing a second subset of the non-volatile storage elements connected to the word line for a second comparison voltage at a second sensing time.

29. The non-volatile storage apparatus of claim 27, wherein:
the one or more control circuits test for different currents through the non-volatile storage elements by charging capacitors associated with the non-volatile storage elements in response to current flowing in at least some of the non-volatile storage elements, sensing a first subset of the non-volatile storage elements connected to the word line for a first comparison voltage by testing whether an associated capacitor has reached a first voltage level and sensing a second subset of the non-volatile storage elements connected to the word line for a second comparison voltage by testing whether an associated capacitor has reached a second voltage level.

30. The non-volatile storage apparatus of claim 27, wherein:
the one or more control circuits sense hard bit and soft bit information by performing a first sensing of the non-volatile storage elements connected to the word line for a read compare voltage and performing a second sensing of the non-volatile storage elements that concurrently tests a first subset of the non-volatile storage elements connected to the word line for a first comparison voltage using a first sensing time and a second subset of the non-volatile storage elements connected to the word line for a second comparison voltage using a second sensing time, the one or more control circuits compute hard bits as a function of the first sensing and the one or more control circuits compute soft bits as a function of the second sensing.
